(19) United States
(12) Patent Application Publication
(10) Pub. No.: US 2024/0266256 A1
(43) Pub. Date: Aug. 8, 2024

(54) SEMICONDUCTOR DEVICE AND METHOD OF FABRICATING THE SAME

(71) Applicant: SAMSUNG ELECTRONICS CO., LTD., Suwon-si (KR)

(72) Inventors: Sangmoon Lee, Suwon-si (KR); Jinbum Kim, Suwon-si (KR)

(73) Assignee: SAMSUNG ELECTRONICS CO., LTD., Suwon-si (KR)

(21) Appl. No.: 18/369,527

(22) Filed: Sep. 18, 2023

(30) Foreign Application Priority Data
Feb. 7, 2023 (KR) 10-2023-0016313

(51) Int. Cl. H01L 23/48; H01L 29/06; H01L 29/08; H01L 29/417; H01L 29/423; H01L 29/775; H01L 29/786

(52) U.S. Cl. CPC H01L 23/481; H01L 29/0673; H01L 29/0847; H01L 29/41733; H01L 29/42392; H01L 29/775; H01L 29/78696

(57) ABSTRACT

The present disclosure provides semiconductor devices including a field effect transistor (FET) and methods of fabricating the same. In some embodiments, a semiconductor device includes a substrate, a lower power line buried in a lower portion of the substrate, a source/drain pattern on the substrate, and a backside contact that penetrates the substrate and electrically couples the lower power line to the source/drain pattern. The backside contact includes an epitaxial pattern coupled to a lower portion of the source/drain pattern, a contact plug coupled to the lower power line, and a metal-semiconductor compound layer between the epitaxial pattern and the contact plug. The epitaxial pattern includes a top surface that protrudes toward the source/drain pattern.

### CROSS-REFERENCE TO RELATED APPLICATIONS

This application claims benefit of priority under 35 U.S.C § 119 to Korean Patent Application No. 10-2023-0016313, filed on Feb. 7, 2023, in the Korean Intellectual Property Office, the disclosure of which is hereby incorporated by reference in its entirety.

### BACKGROUND

### 1. Field

The present disclosure relates generally to semiconductor devices, and more particularly, to a semiconductor device including a field effect transistor (FET) and a method of fabricating the same.

### 2. Description of Related Art

A semiconductor device may include an integrated circuit including metal oxide semiconductor field effect transistors (MOSFETs). As sizes and design rules of the semiconductor device may be gradually decreased, sizes of the MOSFETs may also be increasingly scaled down. However, the scaling down of the MOSFETs may deteriorate operating characteristics of the semiconductor device. Accordingly, there exists a need for further improvements in the fabrication of semiconductor devices, as the need for improved performance may be constrained by limitations caused by high integration of the semiconductordevices.

### SUMMARY

Aspects of the present disclosure provide for a semiconductor device having enhanced electrical properties and improved reliability, when compared to related semiconductordevices.

Aspects of the present disclosure provide a for method of fabricating the semiconductor device having the enhanced electrical properties and the improved reliability.

According to an aspect of the present disclosure, a semiconductor device is provided. The semiconductor device includes a substrate, a lower power line buried in a lower portion of the substrate, a source/drain pattern on the substrate, and a backside contact that penetrates the substrate and electrically couples the lower power line to the source/drain pattern. The backside contact includes an epitaxial pattern coupled to a lower portion of the source/drain pattern, a contact plug coupled to the lower power line, and a metal-semiconductor compound layer between the epitaxial pattern and the contact plug. The epitaxial pattern includes a top surface that protrudes toward the source/drain pattern.

According to an aspect of the present disclosure, a semiconductor device is provided. The semiconductor device includes a dielectric substrate, an etch stop layer on the dielectric substrate, a channel pattern on the etch stop layer, a source/drain pattern coupled to the channel pattern, a gate electrode on the channel pattern, a lower power line below the dielectric substrate, and a backside contact that penetrates the dielectric substrate and electrically couples the lower power line to the source/drain pattern. The channel pattern includes a plurality of semiconductor patterns that are stacked and spaced apart from each other. The gate electrode includes a plurality of inner electrodes that are correspondingly interposed between the plurality of semiconductor patterns. The etch stop layer includes silicon doped with at least one of oxygen (O) and carbon (C). The etch stop layer is between the dielectric substrate and a lowermost electrode of the plurality of inner electrodes.

According to an aspect of the present disclosure, a semiconductor device is provided. The semiconductor device includes a dielectric substrate, an etch stop layer on the dielectric substrate, a channel pattern on the etch stop layer, a source/drain pattern coupled to the channel pattern, a gate electrode on the channel pattern, a gate dielectric layer between the gate electrode and the channel pattern, a gate spacer on a sidewall of the gate electrode, a gate capping pattern on a top surface of the gate electrode, an interlayer dielectric layer that covers the source/drain pattern and the gate capping pattern, a gate contact that penetrates the interlayer dielectric layer and the gate capping pattern and is electrically coupled to the gate electrode, a first metal layer on the interlayer dielectric layer, a lower power line below the dielectric substrate, and a backside contact that penetrates the dielectric substrate and electrically couples the lower power line to the source/drain pattern. The channel pattern includes a plurality of semiconductor patterns that are stacked and spaced apart from each other. The first metal layer includes a first wiring line electrically coupled to the gate contact. The backside contact includes an epitaxial pattern coupled to a lower portion of the source/drain pattern, a contact plug coupled to the lower power line, and a metal-semiconductor compound layer between the epitaxial pattern and the contact plug. A concentration of impurities in the epitaxial pattern is greater than a maximum concentration of impurities in the source/drain pattern.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIGS. 1 to 3 illustrate conceptual views showing logic cells of a semiconductor device, according to some embodiments;

FIG. 4 illustrates a plan view showing a semiconductor device, according to some embodiments;

FIGS. 5A, 5B, 5C, 5D, and 5E illustrate cross-sectional views respectively taken along lines A-A′, B-B′, C-C′, D-D′, and E-E′ of FIG. 4, according to some embodiments;

FIGS. 6A to 15B illustrate cross-sectional views showing a method of fabricating a semiconductor device, according to some embodiments; and

FIG. 16 illustrates a cross-sectional view taken along line A-A′ of FIG. 4, showing a semiconductor device, according to some embodiments.

### DETAILED DESCRIPTION OF EMBODIMENTS

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to described various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

The embodiments herein may be described and illustrated in terms of blocks, as shown in the drawings, which carry out a described function or functions. These blocks, which may be referred to herein as units or modules or the like, or by names such as device, logic, circuit, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

As used herein, each of the terms “AlO”, “BaSrTiO”, “BaTiO”, “CoN”, “CoSi”, “HfD”, “HfSiO”, “HfTaO”, “HfZrO”, “LaO”, “LiO”, “NiN”, “NiSi”, “PbScTaO”, “PbZnNbO”, “PtN”, “SiCN”, “SiCON”, “SiGe”, “SiN”, “SiO”, “SiOC”, “SiOCN”, “SiON”, “SrTiO”, “TaN”, “TaO”, “TaSi”, “TiN”, “TiO”, “TiSi”, “WN”, “Wsi”, “ZrO”, “ZrSiO”, and the like may refer to a material made of elements included in each of the terms and is not a chemical formula representing a stoichiometric relationship.

Hereinafter, various embodiments of the present disclosure are described with reference to the accompanying drawings.

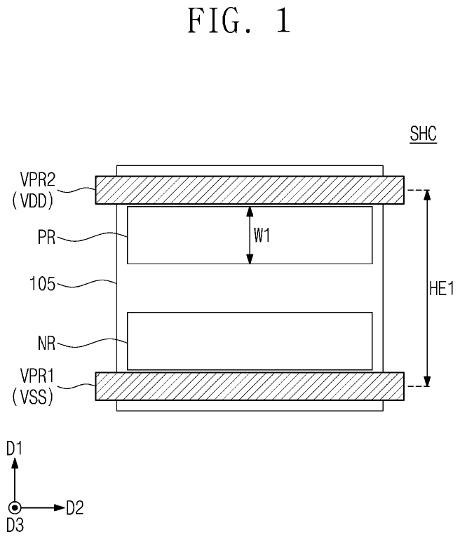

FIGS. 1 to 3 illustrate conceptual views showing logic cells of a semiconductor device, according to some embodiments.

Referring to FIG. 1, a single height cell SHC may be provided. For example, a first lower power line VPR1 and a second lower power line VPR2 may be provided on a lower portion of a substrate 105. The first lower power line VPR1 may be a path for providing a source voltage VSS (e.g., a ground voltage). The second lower power line VPR2 may be a path for providing a drain voltage VDD (e.g., a power voltage).

The single height cell SHC may be disposed between the first lower power line VPR1 and the second lower power line VPR2. The single height cell SHC may include a p-type metal-oxide-semiconductor field-effect transistor (PMOSFET) region PR and an n-type metal-oxide-semiconductor field-effect transistor NMOSFET region NR. For example, the single height cell SHC may have a complementary metal-oxide-semiconductor (CMOS) structure provided between the first lower power line VPR1 and the second lower power line VPR2.

The PMOSFET region PR and the NMOSFET region NR may each have a first width W1 in a first direction D1. A first height HE1 may indicate a length in the first direction D1 of the single height cell SHC. The first height HE1 may be substantially similar and/or the same as a distance (e.g., pitch) between the first lower power line VPR1 and the second lower power line VPR2.

The single height cell SHC may implement a logic cell. As used herein, the logic cell may refer to a logic device that performs a specific function, such as, but not limited to, AND, OR, XOR, XNOR, inverter, and the like. For example, the logic cell may include transistors for implementing a logic device. Alternatively or additionally, the logic cell may include wiring lines that may connect the transistors to each other.

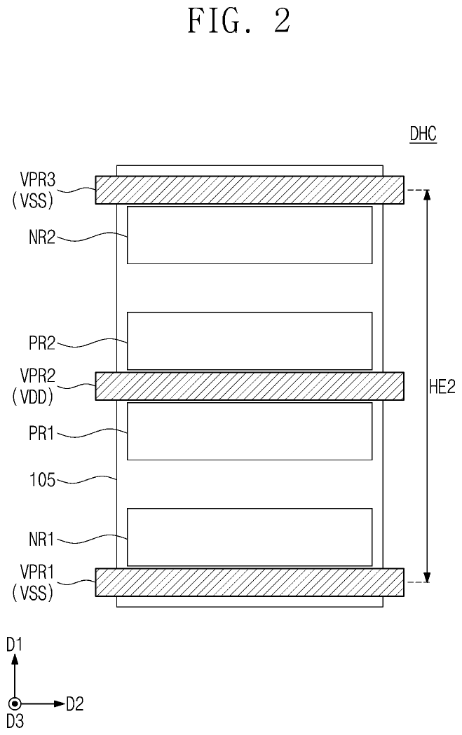

Referring to FIG. 2, a double height cell DHC may be provided. For example, a substrate 105 may be provided thereon with a first lower power line VPR1, a second lower power line VPR2, and a third lower power line VPR3. The second lower power line VPR2 may be disposed between the first lower power line VPR1 and the third lower power line VPR3. The third lower power line VPR3 may be and/or may include a path for providing a source voltage VSS (e.g., a ground voltage).

The double height cell DHC may be disposed between the first lower power line VPR1 and the third lower power line VPR3. The double height cell DHC may include a first PMOSFET region PR1, a second PMOSFET region PR2, a first NMOSFET region NR1, and a second NMOSFET region NR2.

The first NMOSFET region NR1 may be adjacent to the first lower power line VPR1. The second NMOSFET region NR2 may be adjacent to the third lower power line VPR3. The first and second PMOSFET regions PR1 and PR2 may be adjacent to the second lower power line VPR2. When viewed in a plan view, the second lower power line VPR2 may be disposed between the first and second PMOSFET regions PR1 and PR2.

A second height HE2 may indicate a length in the first direction D1 of the double height cell DHC. In an embodiment, the second height HE2 may be about twice the first height HE1 of FIG. 1 (e.g., HE2≈2×HE1). The first and second PMOSFET regions PR1 and PR2 of the double height cell DHC may collectively operate as a single PMOSFET region. Therefore, the double height cell DHC may have a PMOS transistor whose channel size is greater than a channel size of a PMOS transistor included in the single height cell SHC described with reference to FIG. 1.

For example, the channel size of the PMOS transistor included in the double height cell DHC may be about twice (e.g., ×2) a channel size of the PMOS transistor included in the single height cell SHC. That is, the double height cell DHC may operate at a higher speed than an operating speed of the single height cell SHC. In the present disclosure, the double height cell DHC shown in FIG. 2 may be referred to as a multi-height cell. In an embodiment, the multi-height cell may include a triple height cell whose cell height may be about three (3) times a cell height of the single height cell SHC.

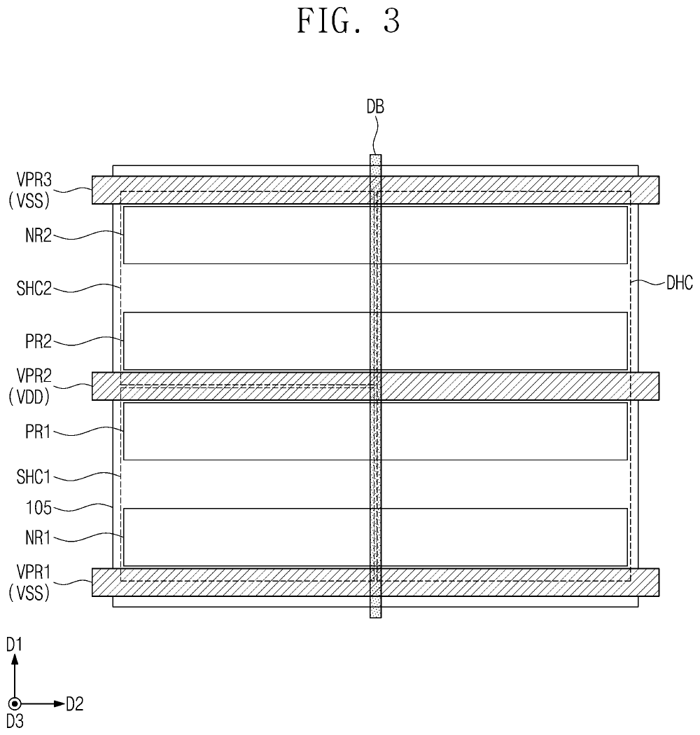

Referring to FIG. 3, a substrate 105 may be provided thereon with a first single height cell SHC1, a second single height cell SHC2, and a double height cell DHC that may be two-dimensionally disposed. The first single height cell SHC1 may be disposed between a first lower power line VPR1 and a second lower power line VPR2. The second single height cell SHC2 may be disposed between the second lower power line VPR2 and a third lower power line VPR3. The second single height cell SHC2 may be adjacent in a first direction D1 to the first single height cell SHC1.

The double height cell DHC may be located between the first lower power line VPR1 and a third lower power line VPR3. The double height cell DHC may be adjacent in a second direction D2 to the first and second single height cells SHC1 and SHC2.

A separation structure DB may be provided between the first single height cell SHC1 and the double height cell DHC and between the second single height cell SHC2 and the double height cell DHC. The separation structure DB may electrically separate (e.g., decouple) an active region of the double height cell DHC from an active region of each of the first and second single height cells SHC1 and SHC2.

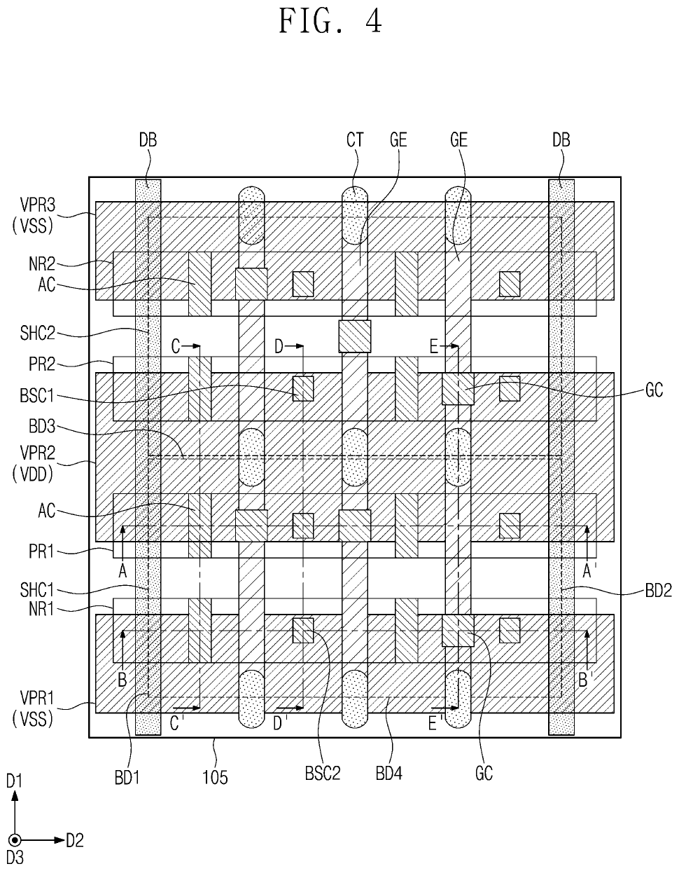

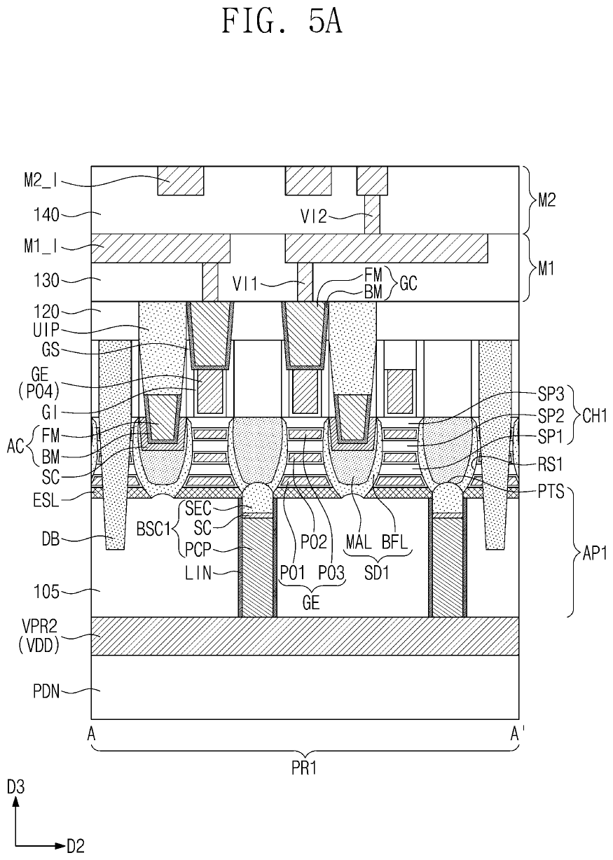

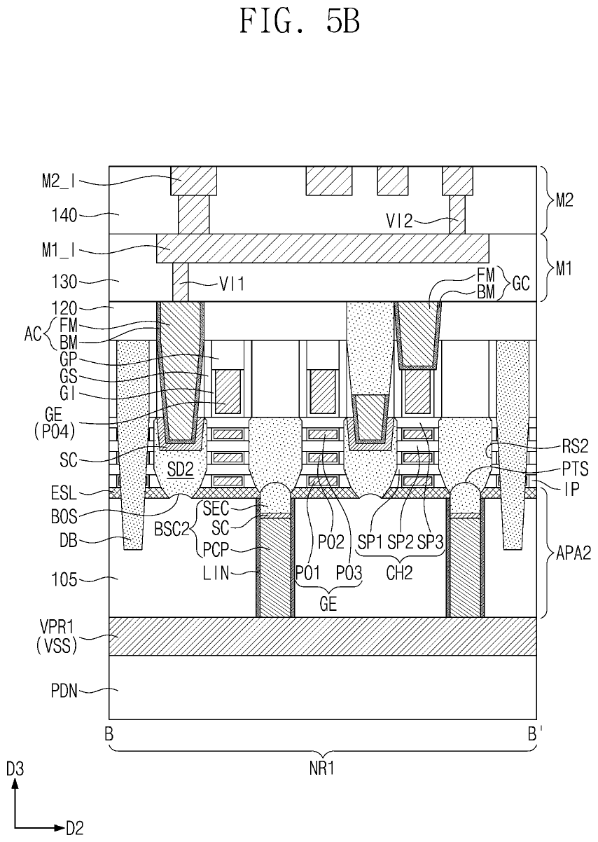

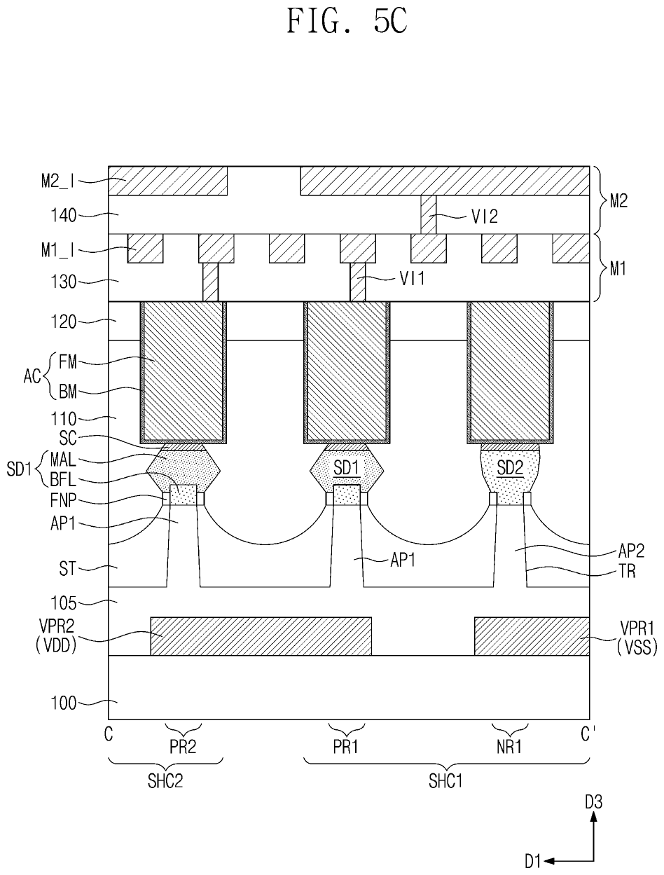

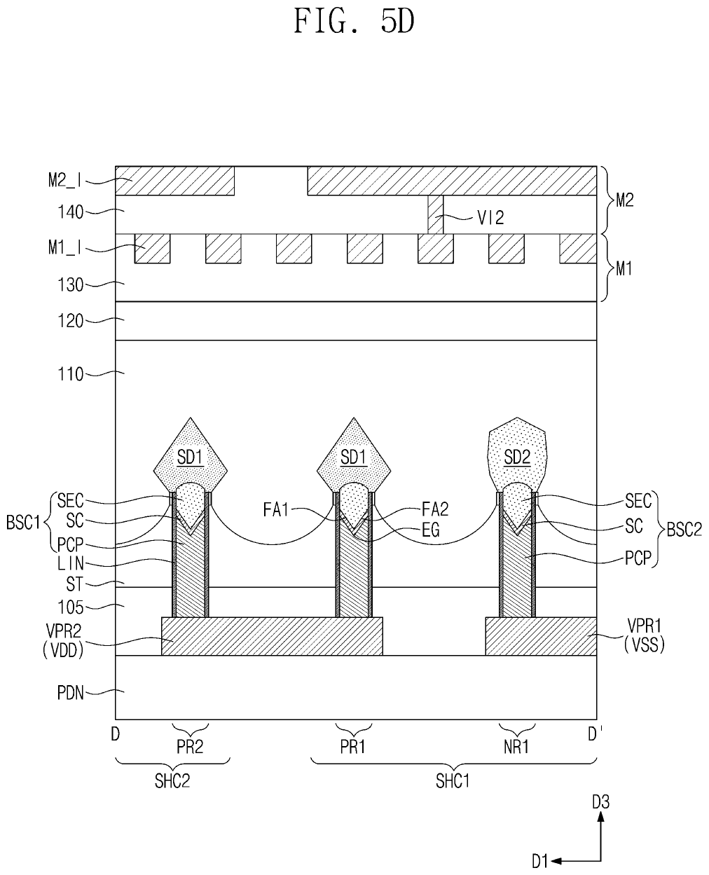

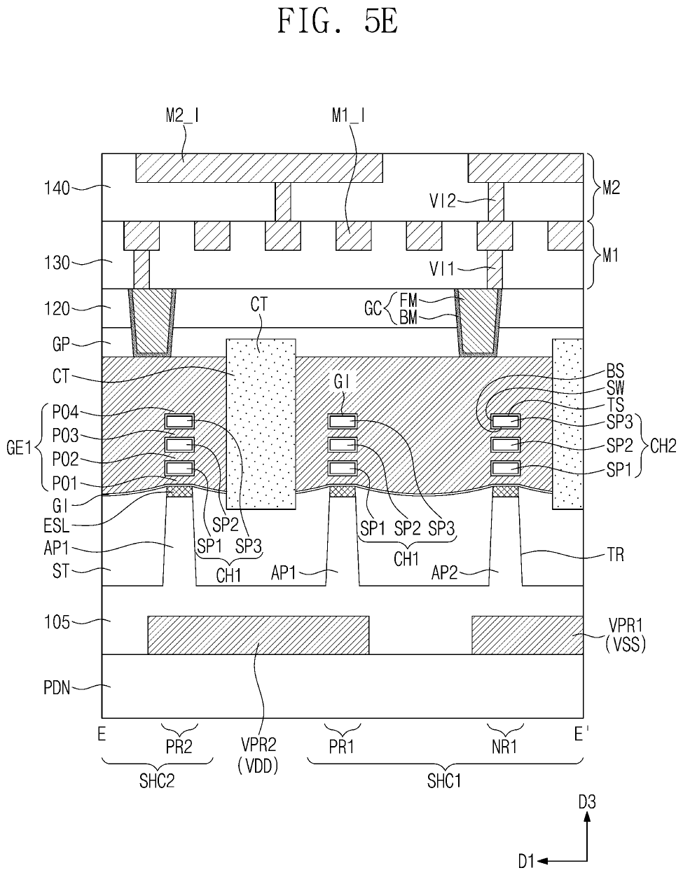

FIG. 4 illustrates a plan view showing a semiconductor device, according to some embodiments. FIGS. 5A, 5B, 5C, 5D, and 5E illustrate cross-sectional views respectively taken along lines A-A′, B-B′, C-C′, D-D′, and E-E′ of FIG. 4, according to some embodiments. A semiconductor device shown in FIGS. 4 and 5A to 5E may be a detailed example of the first and second single height cells SHC1 and SHC2 of FIG. 3.

Referring to FIGS. 4 and 5A to 5E, first and second single height cells SHC1 and SHC2 may be provided on a substrate 105. Each of the first and second single height cells SHC1 and SHC2 may include logic transistors included in a logic circuit. The substrate 105 may be and/or may include a silicon-based dielectric layer. That is, the substrate 105 may be a dielectric substrate. For example, the substrate 105 may include, but not be limited to, a silicon oxide (SiO) layer, a silicon nitride (SiN) layer, or a silicon oxynitride (SiON) layer. In an embodiment, lower power lines VPR1 to VPR3 may be provided in a dielectric layer of the substrate 105, as described below.

The substrate 105 may have a first PMOSFET region PR1, a second PMOSFET region PR2, a first NMOSFET region NR1, and a second NMOSFET region NR2. Each of the first PMOSFET region PR1, the second PMOSFET region PR2, the first NMOSFET region NR1, and the second NMOSFET region NR2 may extend in a second direction D2. The first single height cell SHC1 may include the first NMOSFET region NR1 and the first PMOSFET region PR1. Alternatively or additionally, the second single height cell SHC2 may include the second PMOSFET region PR2 and the second NMOSFET region NR2.

A first dielectric pattern AP1 and a second dielectric pattern AP2 may be demarcated by a trench TR formed on an upper portion of the substrate 105. The first dielectric pattern AP1 may be provided on each of the first and second PMOSFET regions PR1 and PR2. The second dielectric pattern AP2 may be provided on each of the first and second NMOSFET regions NR1 and NR2. The first and second dielectric patterns AP1 and AP2 may extend in the second direction D2. The first and second dielectric patterns AP1 and AP2 may be and/or may include vertically protruding portions of the substrate 105.

In an embodiment, the trench TR may be filled with a device isolation layer ST. The device isolation layer ST may cover at least a portion of a sidewall of each of the first and second dielectric patterns AP1 and AP2. The device isolation layer ST may include a silicon oxide (SiO) layer. Alternatively or additionally, the device isolation layer ST may not cover any of first and second channel patterns CH1 and CH2, as described below.

An etch stop layer ESL may be provided on an upper portion of each of the first and second dielectric patterns AP1 and AP2. The etch stop layer ESL may include a material having an etch selectivity with respect to silicon (Si). For example, the etch stop layer ESL may include, but not be limited to, silicon doped with oxygen (O), carbon (C), and/or a combination thereof. The etch stop layer ESL may be and/or may include a monocrystalline material. In an embodiment, a concentration of impurities (e.g., oxygen, carbon, or a combination thereof) in the etch stop layer ESL may range from about 0.5 atomic percentage (at %) to about 2 at %.

A first channel pattern CH1 may be provided on the first dielectric pattern AP1. A second channel pattern CH2 may be provided on the second dielectric pattern AP2. Each of the first and second channel patterns CH1 and CH2 may include a first semiconductor pattern SP1, a second semiconductor pattern SP2, and a third semiconductor pattern SP3 that may be sequentially stacked. The first to third semiconductor patterns SP1 to SP3 may be spaced apart from each other in a vertical direction (and/or a third direction D3).

Each of the first to third semiconductor patterns SP1 to SP3 may include, but not be limited to, silicon (Si), germanium (Ge), or silicon-germanium (SiGe). For example, each of the first to third semiconductor patterns SP1 to SP3 may be and/or may include a crystalline silicon material. For another example, each of the first to third semiconductor patterns SP1 to SP3 may be and/or may include a nano-sheet.

A plurality of first source/drain patterns SD1 may be provided on the first dielectric pattern AP1. A plurality of first recesses RS1 may be formed on the upper portion of the first dielectric pattern AP1. The first source/drain patterns SD1 may be correspondingly provided in the first recesses RS1. The first source/drain patterns SD1 may be and/or may include impurity regions having a first conductivity type (e.g., p-type). The first channel pattern CH1 may be interposed between a pair of first source/drain patterns SD1. For example, the pair of first source/drain patterns SD1 may be connected to each other through the stacked first to third semiconductor patterns SP1 to SP3.

A plurality of second source/drain patterns SD2 may be provided on the second dielectric pattern AP2. A plurality of second recesses RS2 may be formed on the upper portion of the second dielectric pattern AP2. The second source/drain patterns SD2 may be correspondingly provided in the second recesses RS2. The second source/drain patterns SD2 may be impurity regions having a second conductivity type (e.g., n-type). The second channel pattern CH2 may be interposed between a pair of second source/drain patterns SD2. For example, the pair of second source/drain patterns SD2 may be connected to each other through the stacked first to third semiconductor patterns SP1 to SP3.

The first and second source/drain patterns SD1 and SD2 may be epitaxial patterns formed by a selective epitaxial growth (SEG) process. For example, each of the first and second source/drain patterns SD1 and SD2 may have a top surface located at a level substantially similar and/or the same as a level of a top surface of the third semiconductor pattern SP3. For another example, each of the first and second source/drain patterns SD1 and SD2 may have a top surface located at a higher level than a level of a top surface of the third semiconductor pattern SP3.

The first source/drain patterns SD1 may include a semiconductor element (e.g., silicon-germanium (SiGe)) whose lattice constant may be greater than a lattice constant of a semiconductor element of the first channel pattern CH1. Therefore, a pair of first source/drain patterns SD1 may provide the first channel pattern CH1 with compressive stress. The second source/drain patterns SD2 may include a substantially similar and/or the same semiconductor element (e.g., silicon (Si)) as a semiconductor element of the second channel pattern CH2.

Each of the first source/drain patterns SD1 may include a buffer layer BFL and amain layer MAL on the buffer layer BFL. Referring back to FIG. 5A, the buffer layer BFL may cover an inner wall of the first recess RS1. The buffer layer BFL may occupy a portion of the first recess RS1, and/or the main layer MAL may fill an unoccupied portion of the first recess RS1. In an embodiment, the main layer MAL may have a volume greater than a volume of the buffer layer BFL. Each of the buffer layer BFL and the main layer MAL may include, but not be limited to, silicon-germanium (SiGe). For example, the buffer layer BFL may contain germanium whose concentration may be relatively low. For another example, the buffer layer BFL may not include germanium (Ge), but include only silicon (Si). In an embodiment, the germanium concentration of the buffer layer BFL may range from about 0 at % to about 10 at %.

The main layer MAL may contain germanium (Ge) whose concentration may be relatively high. For example, the germanium concentration of the main layer MAL may range from about 30 at % to about 70 at %. In an embodiment, the germanium concentration of the main layer MAL may increase in the third direction D3. For example, the main layer MAL adjacent to the buffer layer BFL may have a germanium concentration of about 40 at %, and/or an upper portion of the main layer MAL may have a germanium concentration of about 60 at %.

Each of the buffer layer BFL and the main layer MAL may include impurities (e.g., boron (B), gallium (Ga), or indium (In)) that may cause the first source/drain pattern SD1 to have a p-type conductivity. Each of the buffer layer BFL and the main layer MAL may have an impurity concentration of about 1E18 atoms/cm³ to about 5E22 atoms/cm³. In an embodiment, the impurity concentration of the main layer MAL may be greater than an impurity concentration of the buffer layer BFL.

The buffer layer BFL may protect the main layer MAL while second semiconductor layers SAL are replaced with first, second, and third inner electrodes PO1, PO2, and PO3 of a gate electrode GE, as described below. For example, the buffer layer BFL may prevent the main layer MAL from being etched with an etching material that removes the second semiconductor layers SAL.

Each of the second source/drain patterns SD2 may include silicon (Si). The second source/drain pattern SD2 may further include impurities (e.g., phosphorus (P), arsenic (As), or antimony (Sb)) that may cause the second source/drain pattern SD2 to have n-type conductivity. In an embodiment, the second source/drain pattern SD2 may have an impurity concentration of about 1E18 atoms/cm³ to about 5E22 atoms/cm³.

According to an embodiment, each of the first and second source/drain patterns SD1 and SD2 may have a concave bottom BOS. For example, the concave bottom BOS may be concave in the third direction D3.

In an embodiment, gate electrodes GE may be provided to extend in a first direction D1, while running across the first and second channel patterns CH1 and CH2. For example, the gate electrodes GE may be arranged at a first pitch in the second direction D2. Each of the gate electrodes GE may vertically overlap the first and second channel patterns CH1 and CH2.

The gate electrode GE may include a first inner electrode PO1 interposed between the etch stop layer ESL and the first semiconductor pattern SP1. The gate electrode GE may further include a second inner electrode PO2 interposed between the first semiconductor pattern SP1 and the second semiconductor pattern SP2 The gate electrode GE may further include a third inner electrode PO3 interposed between the second semiconductor pattern SP2 and the third semiconductor pattern SP3. The gate electrode GE may further include an outer electrode PO4 on the third semiconductor pattern SP3.

According to an embodiment, the etch stop layer ESL may be interposed between the first inner electrode PO1 and the substrate 105. A gate dielectric layer GI may be interposed between the first inner electrode PO1 and the etch stop layer ESL. The gate dielectric layer GI may directly cover at least a portion of the etch stop layer ESL.

Referring back to FIG. 5E, the gate electrode GE may be provided on a top surface TS, a bottom surface BS, and opposite sidewalls SW of each of the first to third semiconductor patterns SP1 to SP3. For example, a transistor may be and/or may include a three-dimensional field effect transistor (e.g., multibridge-channel metal-oxide-semiconductor field-effect transistor (MBCFET) or Gate-All-Around field-effect transistor (GAAFET)) in which the gate electrode GE three-dimensionally may surround the first and second channel patterns CH1 and CH2.

For example, the first single height cell SHC1 may have a first boundary BD1 and a second boundary BD2 that may be opposite to each other in the second direction D2. The first and second boundaries BD1 and BD2 may extend in the first direction D1. The first single height cell SHC1 may have a third boundary BD3 and a fourth boundary BD4 that may be opposite to each other in the first direction D1. The third and fourth boundaries BD3 and BD4 may extend in the second direction D2.

Gate cutting patterns CT may be located on a boundary in the second direction D2 of each of the first and second single height cells SHC1 and SHC2. For example, the gate cutting patterns CT may be located on the third and fourth boundaries BD3 and BD4 of the first single height cell SHC1. The gate cutting patterns CT may be arranged at the first pitch along the third boundary BD3. The gate cutting patterns CT may be arranged at the first pitch along the fourth boundary BD4. When viewed in a plan view, the gate cutting patterns CT on the third and fourth boundaries BD3 and BD4 may be located to correspondingly overlap the gate electrodes GE. The gate cutting patterns CT may include a dielectric material, such as, but not limited to, a silicon oxide (SiO) layer, a silicon nitride (SiN) layer, or a combination thereof.

The gate cutting pattern CT may separate the gate electrode GE on the first single height cell SHC1 from the gate electrode GE on the second single height cell SHC2. The gate cutting pattern CT may be interposed between the gate electrode GE on the first single height cell SHC1 and the gate electrode GE on the second single height cell SHC2, which gate electrodes GE are aligned with each other in the first direction D1. For example, the gate cutting patterns CT may divide the gate electrode GE, which may extend in the first direction D1, into a plurality of gate electrodes GE.

Referring back to FIGS. 4 and 5A to 5E, a pair of gate spacers GS may be disposed on opposite sidewalls of the outer electrode PO4 included in the gate electrode GE. The gate spacers GS may extend in the first direction D1 along the gate electrode GE. The gate spacers GS may have their top surfaces at a level higher than a level of a top surface of the gate electrode GE. The top surfaces of the gate spacers GS may be coplanar with a top surface of a first interlayer dielectric layer 110, as described below. The gate spacers GS may include, but not be limited to, at least one selected from SiCN, SiCON, and SiN. Alternatively or additionally, the gate spacers GS may each include a multiple layer formed of at least two selected from silicon carbon nitride (SiCN), silicon carbon oxynitride (SiCON), and silicon nitride (SiN).

A gate capping pattern GP may be provided on the gate electrode GE. The gate capping pattern GP may extend in the first direction D1 along the gate electrode GE. The gate capping pattern GP may include a material having an etch selectivity with respect to first and second interlayer dielectric layers 110 and 120, as described below. For example, the gate capping pattern GP may include at least one selected from silicon oxynitride (SiON), silicon carbon nitride (SiCN), silicon carbon oxynitride (SiCON), and silicon nitride (SiN).

A gate dielectric layer GI may be interposed between the gate electrode GE and the first channel pattern CH1 and between the gate electrode GE and the second channel pattern CH2. The gate dielectric layer GI may cover at least a portion of the top surface TS, the bottom surface BS, and/or the opposite sidewalls SW of each of the first to third semiconductor patterns SP1, SP2, and SP3. The gate dielectric layer GI may cover at least a portion of a top surface of the device isolation layer ST below the gate electrode GE. A gate dielectric layer GI may be interposed between the first inner electrode PO1 and the etch stop layer ESL.

In an embodiment, the gate dielectric layer GI may be and/or may include one or more of a silicon oxide (SiO) layer, a silicon oxynitride (SiON) layer, and a high-k dielectric layer. When the gate dielectric layer GI includes a high-k dielectric layer, the high-k dielectric layer may include a high-k dielectric material whose dielectric constant may be greater than a dielectric constant of a silicon oxide (SiO) layer. For example, the high-k dielectric material may include, but not be limited to, one or more of hafnium oxide (HfD), hafnium silicon oxide (HfSiO), hafnium zirconium oxide (HfZrO), hafnium tantalum oxide (HfTaO), lanthanum oxide (LaO), zirconium oxide (ZrO), zirconium silicon oxide (ZrSiO), tantalum oxide (TaO), titanium oxide (TiO), barium strontium titanium oxide (BaSrTiO), barium titanium oxide (BaTiO), strontium titanium oxide (SrTiO), lithium oxide (LiO), aluminum oxide (AlO), lead scandium tantalum oxide (PbScTaO), and lead zinc niobate (PbZnNbO).

The gate electrode GE may include a first metal pattern and/or a second metal pattern on the first metal pattern. The first metal pattern may be provided on the gate dielectric layer GI and/or may be adjacent to the first to third semiconductor patterns SP1 to SP3. The first metal pattern may be and/or may include a work-function metal that may control a threshold voltage of a transistor. A thickness and/or composition of the first metal pattern may be adjusted to potentially achieve a desired threshold voltage of a transistor. For example, the first to third inner electrodes PO1 to PO3 of the gate electrode GE may be formed of the first metal pattern or the work-function metal.

The first metal pattern may include a metal nitride layer. For example, the first metal pattern may include, but not be limited to, nitrogen (N) and/or at least one metal selected from titanium (Ti), tantalum (Ta), aluminum (Al), tungsten (W), and molybdenum (Mo). Alternatively or additionally, the first metal pattern may further include carbon (C). In an embodiment, the first metal pattern may include a plurality of stacked work-function metal layers.

The second metal pattern may include a metal with a resistance that may be less than a resistance of the first metal pattern. For example, the second metal pattern may include, but not be limited to, at least one metal selected from tungsten (W), aluminum (Al), titanium (Ti), and tantalum (Ta). For example, the outer electrode PO4 of the gate electrode GE may include a first metal pattern and a second metal pattern on the first metal pattern.

Referring back to FIG. 5B, inner spacers IP may be provided on the first and second NMOSFET regions NR1 and NR2. For example, the inner spacers IP may be provided on the second dielectric pattern AP2. The inner spacers IP may be correspondingly interposed between the second source/drain pattern SD2 and the first to third inner electrodes PO to PO3 of the gate electrode GE. The inner spacers IP may be in direct contact with the second source/drain pattern SD2. The inner spacer IP may separate the second source/drain pattern SD2 from each of the first to third inner electrodes PO1 to PO3 of the gate electrode GE.

A first interlayer dielectric layer 110 may be provided on the substrate 105. The first interlayer dielectric layer 110 may cover at least a portion of the gate spacers GS and the first and second source/drain patterns SD1 and SD2. The first interlayer dielectric layer 110 may have a top surface that may be substantially coplanar with a top surface of the gate capping pattern GP and a top surface of the gate spacer GS. The first interlayer dielectric layer 110 may be provided thereon with a second interlayer dielectric layer 120 that may cover at least a portion of the gate capping pattern GP. A third interlayer dielectric layer 130 may be provided on the second interlayer dielectric layer 120. A fourth interlayer dielectric layer 140 may be provided on the third interlayer dielectric layer 130. For example, the first to fourth interlayer dielectric layers 110 to 140 may include, but not be limited to, a silicon oxide (SiO) layer.

Each of the first and second single height cells SHC1 and SHC2 may be provided on its opposite sides with a pair of separation structures DB that may be opposite to each other in the second direction D2. For example, the pair of separation structures DB may be correspondingly provided on first and second boundaries BD1 and BD2 of the first single height cell SHC1. The separation structure DB may extend in the first direction D1 parallel to the gate electrodes GE. A pitch between the separation structure DB and its adjacent gate electrode GE may be a substantially similar and/or the same pitch as the first pitch.

The separation structure DB may penetrate the gate capping pattern GP and the gate electrode GE to extend into the first and second dielectric patterns AP1 and AP2. The separation structure DB may penetrate the upper portion of each of the first and second dielectric patterns AP1 and AP2. The separation structure DB may electrically separate (e.g., decouple) an active region of each of the first and second single height cells SHC1 and SHC2 from an active region of another cell.

Active contacts AC may be provided to penetrate the first and second interlayer dielectric layers 110 and 120 to come into electrical connection with the first and second source/drain patterns SD1 and SD2. Each of the active contacts AC may be provided to adjoin one side of the gate electrode GE. When viewed in a plan view, the active contact AC may have a bar shape that extends in the first direction D1.

In an embodiment, the active contact AC may be a self-aligned contact. For example, the gate capping pattern GP and the gate spacer GS may be used to form the active contact AC in a self-alignment manner. The active contact AC may cover, for example, at least a portion of a sidewall of the gate spacer GS. In an embodiment, the active contact AC may cover a portion of the top surface of the gate capping pattern GP.

A metal-semiconductor compound layer SC, such as, but not limited to, a silicide layer, may be interposed between the active contact AC and the first source/drain pattern SD1 and between the active contact AC and the second source/drain pattern SD2. The active contact AC may be electrically connected through the metal-semiconductor compound layer SC to one of the first and second source/drain patterns SD1 and SD2. For example, the metal-semiconductor compound layer SC may include, but not be limited to, at least one selected from titanium silicide (TiSi), tantalum silicide (TaSi), tungsten silicide (WSi), nickel silicide (NiSi), and cobalt silicide (CoSi).

Gate contacts GC may be provided to penetrate the second interlayer dielectric layer 120 and the gate capping pattern GP to come into electrical connection with the gate electrodes GE. When viewed in a plan view, two gate contacts GC on the first single height cell SHC1 may be located to overlap the first PMOSFET region PR1. For example, two gate contacts GC on the first single height cell SHC1 may be provided on the first dielectric pattern AP1 (e.g., as shown in FIG. 5A). When viewed in a plan view, one gate contact GC on the first single height cell SHC1 may be located to overlap the first NMOSFET region NR1. For example, one gate contact GC on the first single height cell SHC1 may be provided on the second dielectric pattern AP2 (e.g., as shown in FIG. 5B).

The gate contact GC may be freely located with no limitation of position on the gate electrode GE. For example, the gate contacts GC on the second single height cell SHC2 may be correspondingly located on the second PMOSFET region PR2, the second NMOSFET region NR2, and the device isolation layer ST that fills the trench TR (e.g., as shown in FIG. 4).

In an embodiment, referring to FIG. 5B, the active contact AC may have an upper portion adjacent to the gate contact GC, and an upper dielectric pattern UIP may fill the upper portion of the active contact AC. The upper dielectric pattern UIP may have a bottom surface lower than a bottom surface of the gate contact GC. For example, the upper dielectric pattern UIP may cause the active contact AC adjacent to the gate contact GC to have a top surface lower than the bottom surface of the gate contact GC. Therefore, it may be possible to prevent a short circuit resulting from contact between the gate contact GC and an adjacent active contact AC. For example, the upper dielectric pattern UIP may include a silicon-based dielectric material (e.g., a silicon oxide (SiO) layer, a silicon nitride (SiN) layer, a silicon oxynitride (SiON) layer).

Each of the active contact AC and the gate contact GC may include a conductive pattern FM and/or a barrier pattern BM that may surround the conductive pattern FM. For example, the conductive pattern FM may include, but not be limited to, at least one metal selected from aluminum (Al), copper (Cu), tungsten (W), molybdenum (Mo), and cobalt (Co). The barrier pattern BM may cover at least a portion of sidewalls and/or a bottom surface of the conductive pattern FM. The barrier pattern BM may include a metal layer and/or a metal nitride layer. The metal layer may include, but not be limited to, at least one selected from titanium (Ti), tantalum (Ta), tungsten (W), nickel (Ni), cobalt (Co), and platinum (Pt). The metal nitride layer may include, but not be limited to, at least one selected from a titanium nitride (TiN) layer, a tantalum nitride (TaN) layer, a tungsten nitride (WN) layer, a nickel nitride (NiN) layer, a cobalt nitride (CoN) layer, and a platinum nitride (PtN) layer.

Referring back to FIGS. 4 and 5C to 5E, first to third lower power lines VPR1 to VPR3 may be provided on a lower portion of the substrate 105. The first to third lower power lines VPR1 to VPR3 may extend in parallel to each other in the second direction D2. The first lower power line VPR1 may be disposed on the fourth boundary BD4 of the first single height cell SHC1. The second lower power line VPR2 may be disposed on the third boundary BD3 of the first single height cell SHC1. For example, the first single height cell SHC1 may be disposed between the first lower power line VPR1 and the second lower power line VPR2. The second single height cell SHC2 may be disposed between the second lower power line VPR2 and the third lower power line VPR3.

In an embodiment, the first lower power line VPR1 may vertically overlap the first NMOSFET region NR1. Alternatively or additionally, the second lower power line VPR2 may vertically overlap the first PMOSFET region PR1 and the second PMOSFET region PR2. In an optional or additional embodiment, the third lower power line VPR3 may vertically overlap the second NMOSFET region NR2.

The first to third lower power lines VPR1 to VPR3 may include, but not be limited to, at least one selected from copper (Cu), molybdenum (Mo), tungsten (W), and ruthenium (Ru). Each of the first to third lower power lines VPR1 to VPR3 may have a bottom surface coplanar with a bottom surface of the substrate 105.

A power delivery network layer PDN may be provided on a bottom surface of the substrate 105. The power delivery network layer PDN may include a plurality of lower lines electrically connected to the first to third lower power lines VPR1 to VPR3. For example, the power delivery network layer PDN may include a wiring network for applying a source voltage VSS to the first and third lower power lines VPR1 and VPR3. Alternatively or additionally, the power delivery network layer PDN may include a wiring network for applying a drain voltage VDD to the second lower power line VPR2.

Referring back to FIGS. 4, 5A, 5B, and 5D, a first backside contact BSC1 may be provided to penetrate the substrate 105 to vertically extend from the second lower power line VPR2 to the first source/drain pattern SD1. A second backside contact BSC2 may be provided to penetrate the substrate 105 to vertically extend from the first lower power line VPR1 to the second source/drain pattern SD2.

The first backside contact BSC1 may have a conductive pillar shape that vertically and electrically connect the second lower power line VPR2 to the first source/drain pattern SD1. The drain voltage VDD may be applied through the first backside contact BSC1 to the first source/drain pattern SD1.

The second backside contact BSC2 may have a conductive pillar shape that vertically and electrically connect the first lower power line VPR1 to the second source/drain pattern SD2. The source voltage VSS may be applied through the second backside contact BSC2 to the second source/drain pattern SD2.

Each of the first and second backside contacts BSC1 and BSC2 may include a contact plug PCP connected to one of the lower power lines VPR1 to VPR3, an epitaxial contact SEC connected to one of the source/drain patterns SD1 and SD2, and a metal-semiconductor compound layer SC between the epitaxial contact SEC and the contact plug PCP. A liner LIN may be interposed between the substrate 105 and each of the first and second backside contacts BSC1 and BSC2.

The contact plug PCP may include, but not be limited to, at least one metal selected from tungsten (W), molybdenum (Mo), ruthenium (Ru), cobalt (Co), aluminum (Al), and copper (Cu). The epitaxial contact SEC may include a semiconductor material, such as, but not be limited to, silicon (Si), germanium (Ge), or silicon-germanium (SiGe). The liner LIN may include, but not be limited to, a silicon-based dielectric material (e.g, silicon oxide (SiO), silicon nitride (SiN), silicon carbon oxide (SiOC), or silicon carbon oxynitride (SiOCN)).

The epitaxial contact SEC may have a top surface PTS that may protrude toward one of the source/drain patterns SD1 and SD2. The top surface PTS of the epitaxial contact SEC may have a profile that may be convex toward one of the source/drain patterns SD1 and SD2. When the epitaxial contact SEC has the convex top surface PTS, an increased contact area may be provided between the epitaxial contact SEC and one of the source/drain patterns SD1 and SD2. In an embodiment, at least a portion of the epitaxial contact SEC may be in direct contact with the etch stop layer ESL (e.g., as shown in FIGS. 5A and 5B).

The epitaxial contact SEC may include impurities whose concentration may be relatively high. For example, the epitaxial contact SEC of the first backside contact BSC1 may include impurities such as, but not limited to, boron (B), gallium (Ga), indium (In), or aluminum (Al). Alternatively or additionally, the epitaxial contact SEC of the first backside contact BSC1 may have an impurity concentration greater than a maximum concentration of impurities in the first source/drain pattern SD1.

For example, the epitaxial contact SEC of the second backside contact BSC2 may include impurities such as, but not limited to, phosphorus (P), arsenic (As), or antimony (Sb). The epitaxial contact SEC of the second backside contact BSC2 may have an impurity concentration greater than a maximum concentration of impurities in the second source/drain pattern SD2.

The epitaxial contact SEC may be and/or may include a semiconductor pattern grown from a seed and/or the source/drain pattern SD1 or SD2 connected thereto, and thus, the epitaxial contact SEC may have a crystal structure that may be substantially similar and/or the same as a crystal structure of the source/drain pattern SD1 or SD2.

In an embodiment, referring to FIG. 5D, the epitaxial contact SEC may have a bottom surface including a first crystal plane FA1 and a second crystal plane FA2. Each of the first and second crystal planes FA1 and FA2 may be a {111} plane. The first and second crystal planes FA1 and FA2 may meet each other to define a sharp corner EG. The corner EG may be a lowermost point of the epitaxial contact SEC.

Referring back to FIGS. 4 and 5A to 5E, a first metal layer M1 may be provided in the third interlayer dielectric layer 130. The first metal layer M1 may include first wiring lines M1_I. The first wiring lines M1_I of the first metal layer M1 may extend parallel to each other in the second direction D2.

According to some embodiments, a power line for supplying power to the single height cell SHC1 or SHC2 may be provided as the lower power lines VPR1 to VPR3 buried in the substrate 105. Therefore, a power line may be omitted in the first metal layer M1. In an optional or additional embodiment, the first metal layer M1 may be provided therein with the first wiring lines M1_I for signal transfer.

The first metal layer M1 may further include first vias VI1. The first vias VI1 may be correspondingly provided below the first wiring lines M1_I of the first metal layer M1. The active contact AC may be electrically connected through the first via VI1 to the first wiring line M1_I of the first metal layer M1. The gate contact GC may be electrically connected through the first via VI1 to the first wiring line M1_I of the first metal layer M1.

The first wiring line M1_I and its underlying first via VI1 of the first metal layer M1 may be formed by individual processes. For example, the first wiring line M1_I and the first via VI1 of the first metal layer M1 may each be formed by a single damascene process. A sub-20 nanometer (nm) process may be employed to fabricate a semiconductor device, according to some embodiments.

A second metal layer M2 may be provided in the fourth interlayer dielectric layer 140. The second metal layer M2 may include a plurality of second wiring lines M2_I. The second wiring lines M2_I of the second metal layer M2 may each have a linear and/or bar shape that may extend in the first direction D1. For example, the second wiring lines M2_I may extend parallel to each other in the first direction D1.

The second metal layer M2 may further include second vias VI2 that may be correspondingly provided below the second wiring lines M2_I. The first wiring line M1_I of the first metal layer M1 may be electrically connected through the second via VI2 to the second wiring line M2_I of the second metal layer M2. For example, a dual damascene process may be employed to substantially simultaneously form the second wiring line M2_I and its underlying second via VI2 of the second metal layer M2.

The first wiring line M1_I of the first metal layer M1 and the second wiring line M2_I of the second metal layer M2 may include the same and/or different conductive materials. For example, the first wiring line M1_I of the first metal layer M1 and the second wiring line M2_I of the second metal layer M2 may include, but not be limited to, at least one metallic material selected from aluminum (Al), copper (Cu), tungsten (W), molybdenum (Mo), ruthenium (Ru), and cobalt (Co). In an embodiment, other metal layers (e.g., M3, M4, M5, and the like) may be additionally stacked on the fourth interlayer dielectric layer 140. Each of the stacked metal layers may include wiring lines for routing between cells.

In a semiconductor device, according to some embodiments, the etch stop layer ESL may be used to remove a semiconductor substrate 100, as described below. For example, the semiconductor substrate 100 may be replaced through the etch stop layer ESL with the substrate 105 and/or a dielectric substrate. Therefore, it may be possible to prevent and/or reduce a leakage current from NMOSFET and PMOSFET toward the substrate 105 and/or to improve electrical properties of devices.

According to some embodiments, the backside contact BSC1 or BSC2 may be connected in a self-alignment manner through the epitaxial contact SEC to the source/drain pattern SD1 or SD2. When the epitaxial contact SEC has the high impurity concentration and the convex top surface PTS, a reduced contact resistance may be provided between the backside contacts BSC1 and BSC2 and the source/drain patterns SD1 and SD2. As a result, a semiconductor device including a lower power line, according to the present disclosure, may have increased reliability and/or improved electrical properties, when compared to a related semiconductor device.

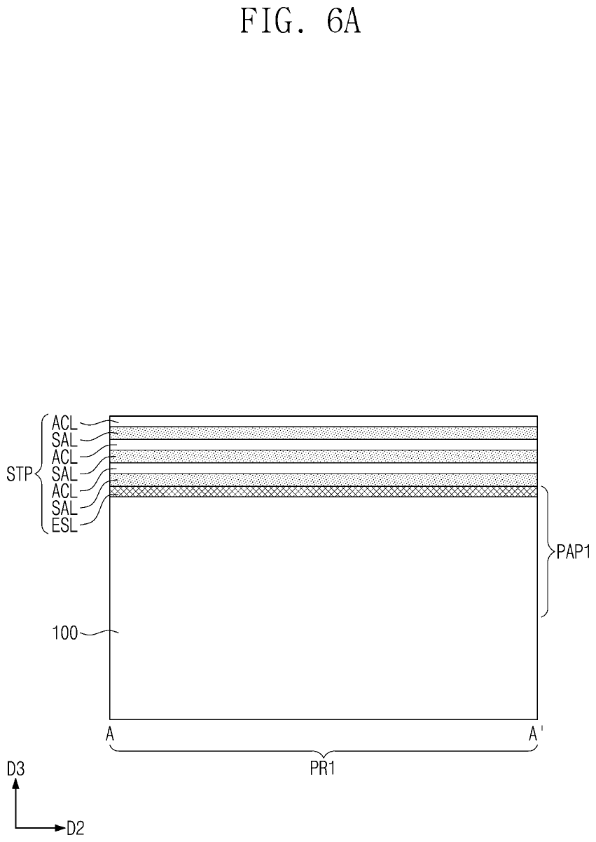

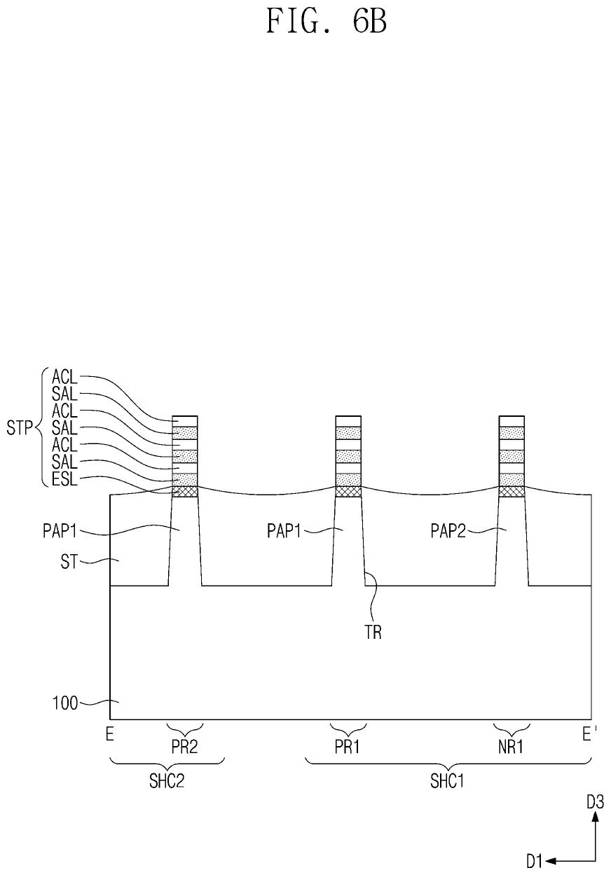

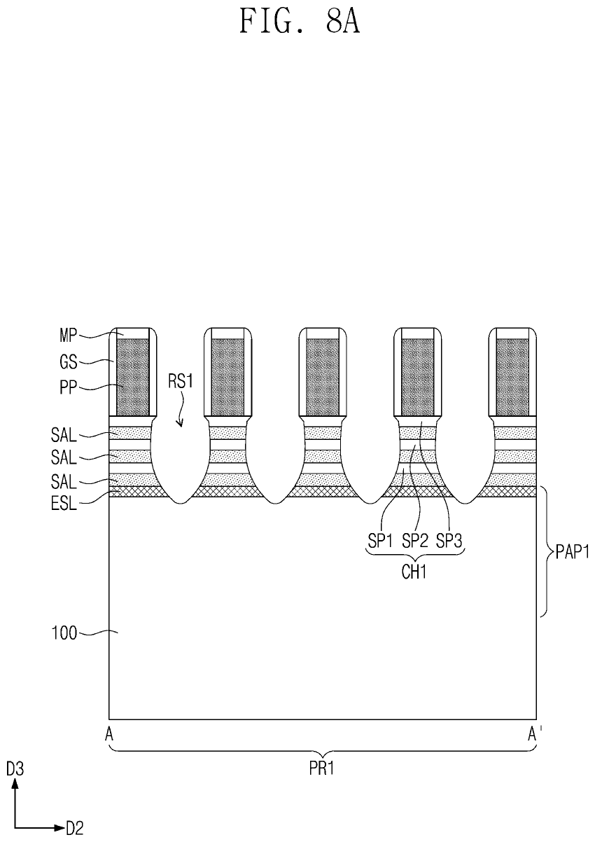

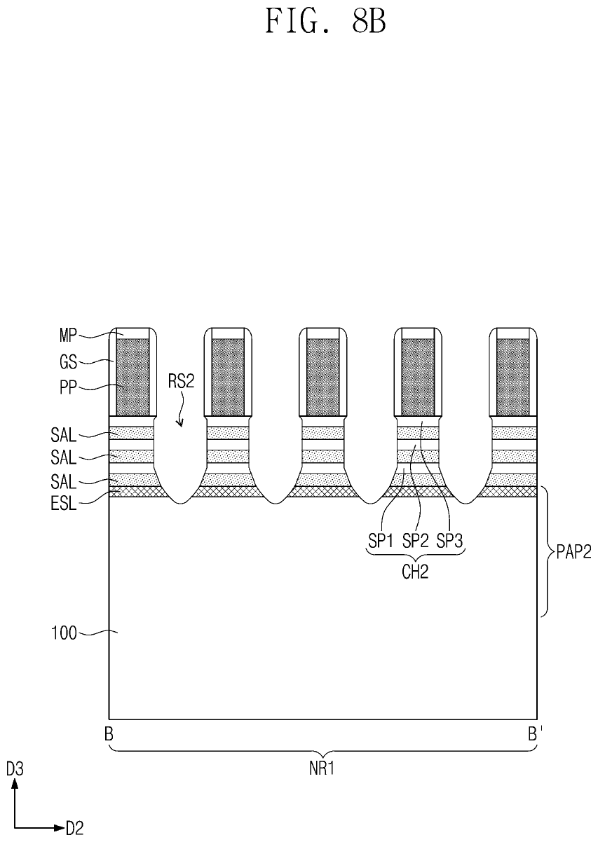

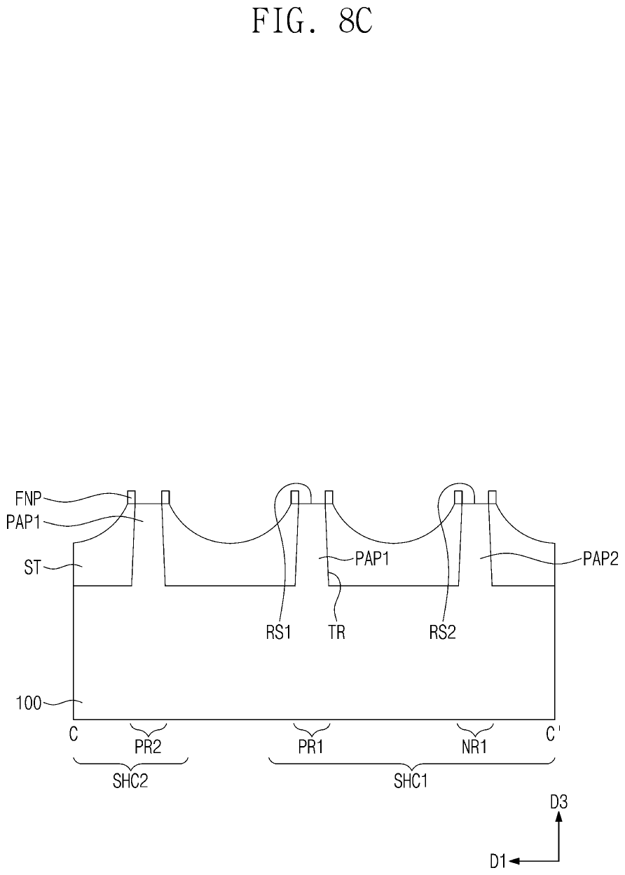

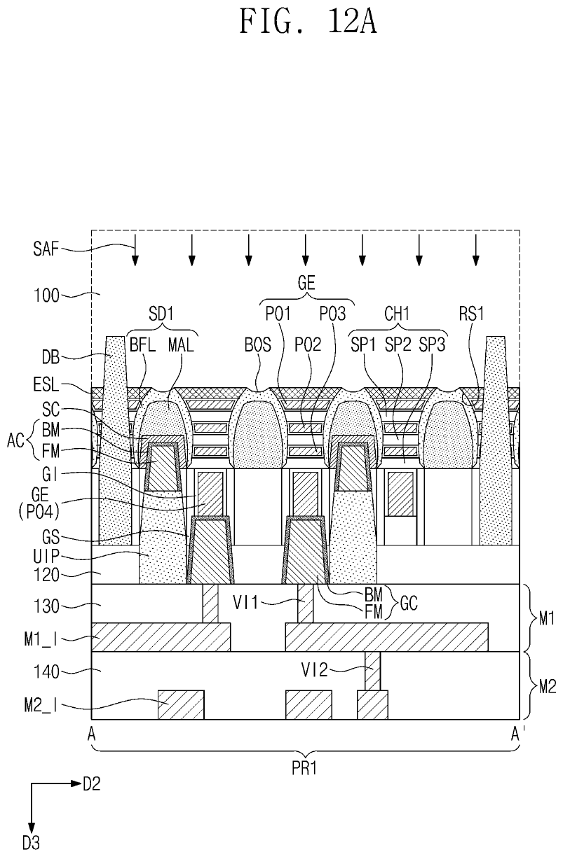

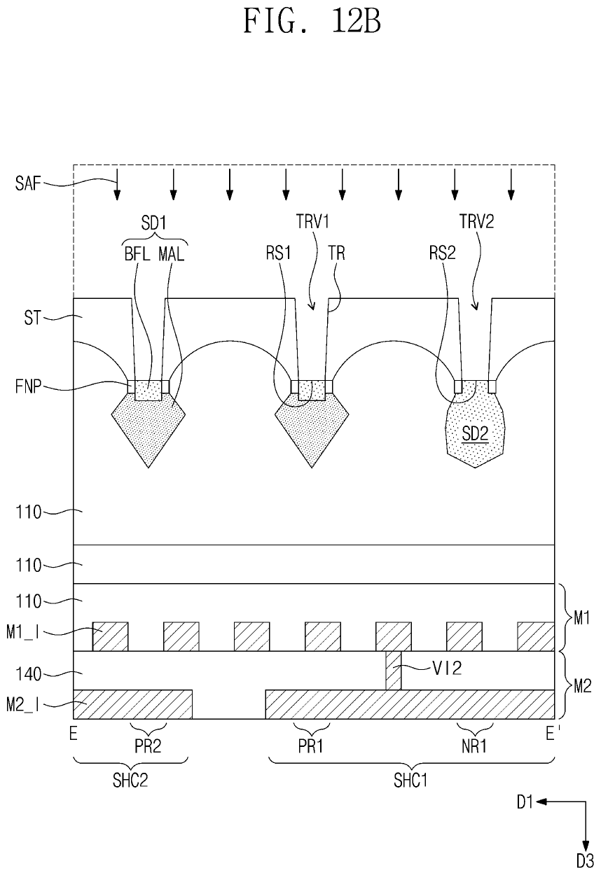

FIGS. 6A to 15B illustrate cross-sectional views showing a method of fabricating a semiconductor device according to some embodiments. For example, FIGS. 6A, 7A, 8A, 9A, 10A, 11A, 12A, 13A, 14A, and 15A illustrate cross-sectional views taken along line A-A′ of FIG. 4. FIGS. 8B, 9B, 10B, and 11B illustrate cross-sectional views taken along line B-B′ of FIG. 4. FIGS. 8C, 9C, and 11C illustrate cross-sectional views taken along line C-C′ of FIG. 4. FIGS. 12B, 13B, 14B, and 15B illustrate cross-sectional views taken along line D-D′ of FIG. 4. FIGS. 6B, 7B, 10C, and 11D illustrate cross-sectional views taken along line E-E′ of FIG. 4.

Referring to FIGS. 6A and 6B, a semiconductor substrate 100 may be provided which includes first and second PMOSFET regions PR1 and PR2 and first and second NMOSFET regions NR1 and NR2. For example, the semiconductor substrate 100 may be and/or may include a silicon wafer. Alternatively or additionally, an etch stop layer ESL may be formed on the semiconductor substrate 100. The etch stop layer ESL may be formed to have an etch selectivity with respect to the semiconductor substrate 100 and/or silicon (Si).

For example, the formation of the etch stop layer ESL may include performing a selective epitaxial growth (SEG) process on the semiconductor substrate 100. During the SEG process, impurities (e.g., oxygen (O), carbon (C), or a combination thereof) may be in-situ implanted. As such, the etch stop layer ESL formed on the semiconductor substrate 100 may include silicon doped with oxygen (O), carbon (C), or a combination thereof. A concentration of impurities (e.g., oxygen, carbon, or a combination thereof) in the etch stop layer ESL may range from about 0.5 at % to about 2 at %.

First semiconductor layers ACL and second semiconductor layers SAL may be alternately stacked on the etch stop layer ESL. The first semiconductor layers ACL may include, but not be limited to, at least one of silicon (Si), germanium (Ge), and silicon-germanium (SiGe). The second semiconductor layers SAL may include, but not be limited to, at least another of silicon (Si), germanium (Ge), and silicon-germanium (SiGe).

The second semiconductor layer SAL may include a material having an etch selectivity with respect to the first semiconductor layer ACL. For example, the first semiconductor layers ACL may include, but not be limited to, silicon (Si). Alternatively or additionally, the second semiconductor layers SAL may include, but not be limited to, silicon-germanium (SiGe). For example, a concentration of germanium (Ge) in each of the second semiconductor layers SAL may range from about 10 at % to about 30 at %.

Mask patterns may be formed on the first and second PMOSFET regions PR1 and PR2 and the first and second NMOSFET regions NR1 and NR2 of the semiconductor substrate 100. The mask pattern may have a linear and/or bar shape that may extend in a second direction D2.

A patterning process may be performed in which the mask patterns may be used as an etching mask to form a trench TR that may delineate a first active pattern PAP1 and/or a second active pattern PAP2. The first active pattern PAP1 may be formed on each of the first and second PMOSFET regions PR1 and PR2. The second active pattern PAP2 may be formed on each of the first and second NMOSFET regions NR1 and NR2. When viewed in a plan view, the first and second active patterns PAP1 and PAP2 may have linear shapes that may extend in parallel in a second direction D2.

A stack pattern STP may be formed on each of the first and second active patterns PAP1 and PAP2. The stack pattern STP may include the etch stop layer ESL. The stack pattern STP may further include the first semiconductor layers ACL and the second semiconductor layers SAL that may be alternately stacked on the etch stop layer ESL. During the patterning process, the stack pattern STP may be formed together (e.g., at a substantially similar time) with the first and second active patterns PAP1 and PAP2.

A device isolation layer ST may be formed to fill the trench TR. For example, a dielectric layer may be formed on a surface of the semiconductor substrate 100 to cover at least a portion of the stack patterns STP and the first and second active patterns PAP1 and PAP2. The dielectric layer may be recessed until the stack patterns STP are exposed, and thus, the device isolation layer ST may be formed.

The device isolation layer ST may include a dielectric material, such as, but not limited to, a silicon oxide (SiO) layer. The stack patterns STP may be exposed upwardly from the device isolation layer ST. For example, the stack patterns STP may vertically protrude upwards from the device isolation layer ST.

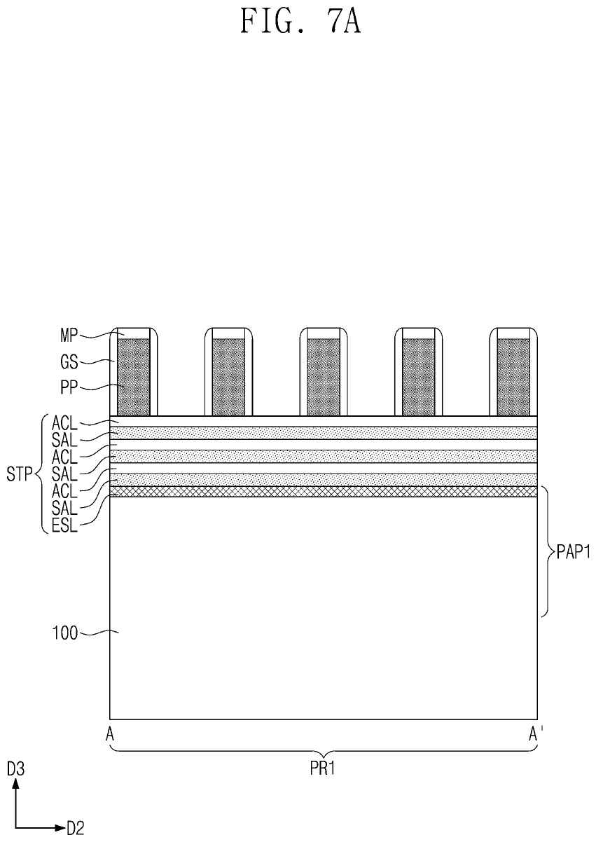

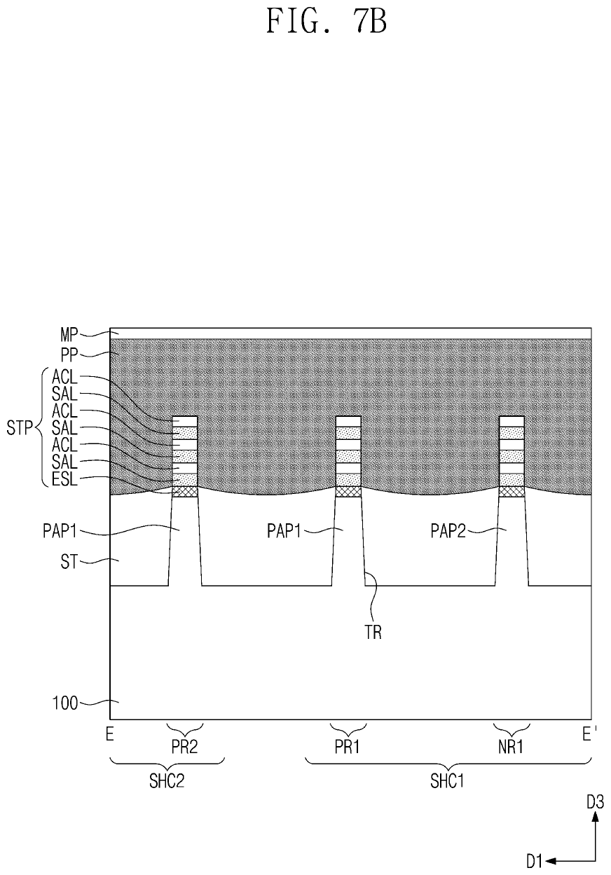

Referring to FIGS. 7A and 7B, sacrificial patterns PP may be formed on the semiconductor substrate 100, running across the stack patterns STP. Each of the sacrificial patterns PP may be formed to have a linear and/or bar shape that may extend in a first direction D1. The sacrificial patterns PP may be arranged at a first pitch along the second direction D2.

For example, the formation of the sacrificial patterns PP may include forming a sacrificial layer on the entire surface of the semiconductor substrate 100, forming hardmask patterns MP on the sacrificial layer, and using the hardmask patterns MP as an etching mask to pattern the sacrificial layer. For another example, the sacrificial layer may include a polysilicon material.

A pair of gate spacers GS may be formed on opposite sidewalls of each of the sacrificial patterns PP. The formation of the gate spacers GS may include conformally forming a gate spacer layer on the entire surface of the semiconductor substrate 100 and/or anisotropically etching the gate spacer layer. The gate spacer layer may include, but not be limited to, at least one selected from silicon carbon nitride (SiCN), silicon carbon oxynitride (SiCON), and silicon nitride (SiN). Alternatively or additionally, the gate spacer layer may be a multiple layer including at least two selected from silicon carbon nitride (SiCN), silicon carbon oxynitride (SiCON), and silicon nitride (SiN).

Referring to FIGS. 8A and 8B, first recesses RS1 may be formed in the stack pattern STP on the first active pattern PAP1. Alternatively or additionally, second recesses RS2 may be formed in the stack pattern STP on the second active pattern PAP2. During the formation of the first and second recesses RS1 and RS2, the device isolation layer ST may be further recessed on opposite sides of each of the first and second active patterns PAP1 and PAP2 (e.g., as shown in FIG. 8C).

For example, the hardmask patterns MP and the gate spacers GS may be used as an etching mask such that the stack pattern STP on the first active pattern PAP1 may be etched to form the first recesses RS1. The first recess RS1 may be formed between a pair of sacrificial patterns PP. The second recesses RS2 in the stack pattern STP on the second active pattern PAP2 may be formed by a substantially similar and/or the same method as a method used for the formation of the first recesses RS1.

Referring back to FIG. 8C, a fence pattern FNP may be formed on each of the first and second active patterns PAP1 and PAP2. The fence pattern FNP may be a portion of the gate spacer GS that remains.

Referring back to FIGS. 8A to 8C, the first semiconductor layers ACL may be formed into first to third semiconductor patterns SP1 to SP3 that may be sequentially stacked between neighboring first recesses RS1. The first semiconductor layers ACL may be formed into first to third semiconductor patterns SP1 to SP3 that may be sequentially stacked between neighboring second recesses RS2. A first channel pattern CH1 may be implemented by the first to third semiconductor patterns SP1 to SP3 between neighboring first recesses RS1. A second channel pattern CH2 may be implemented by the first to third semiconductor patterns SP1 to SP3 between neighboring second recesses RS2.

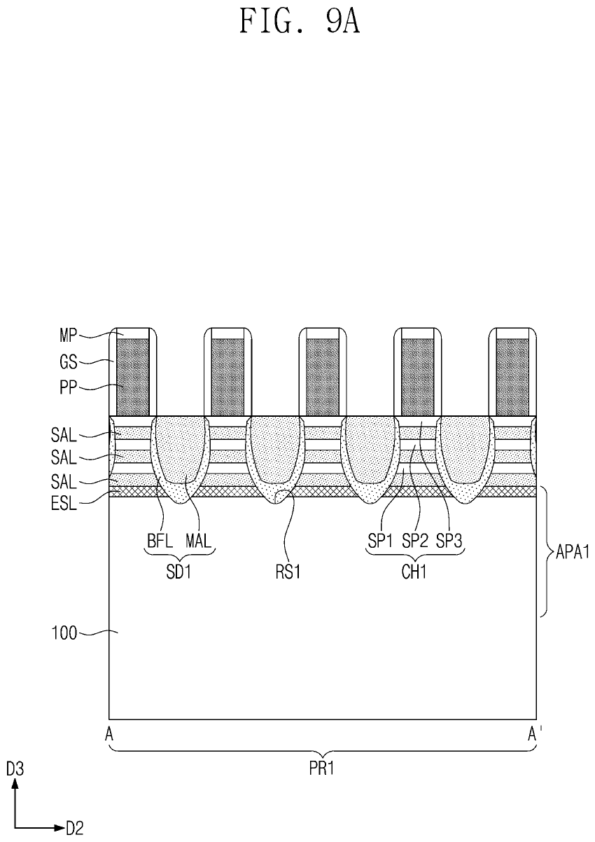

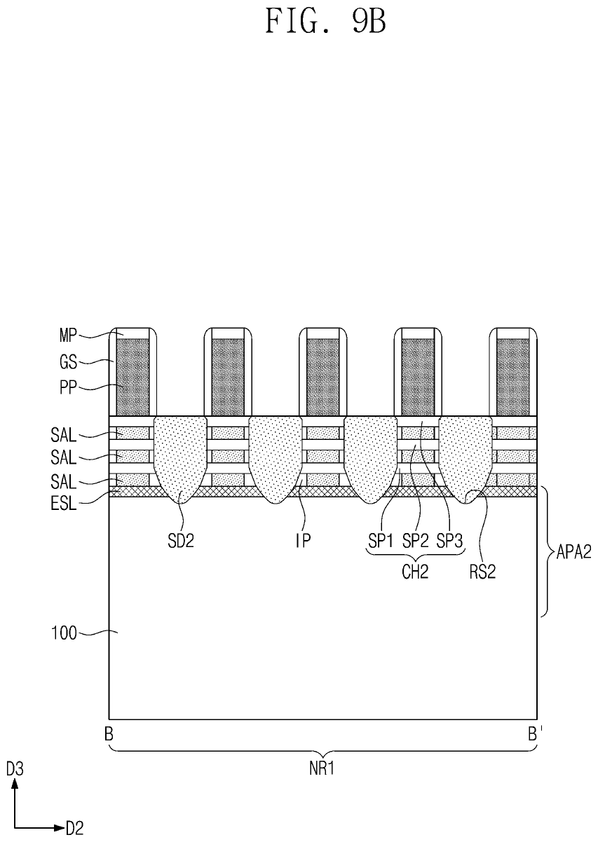

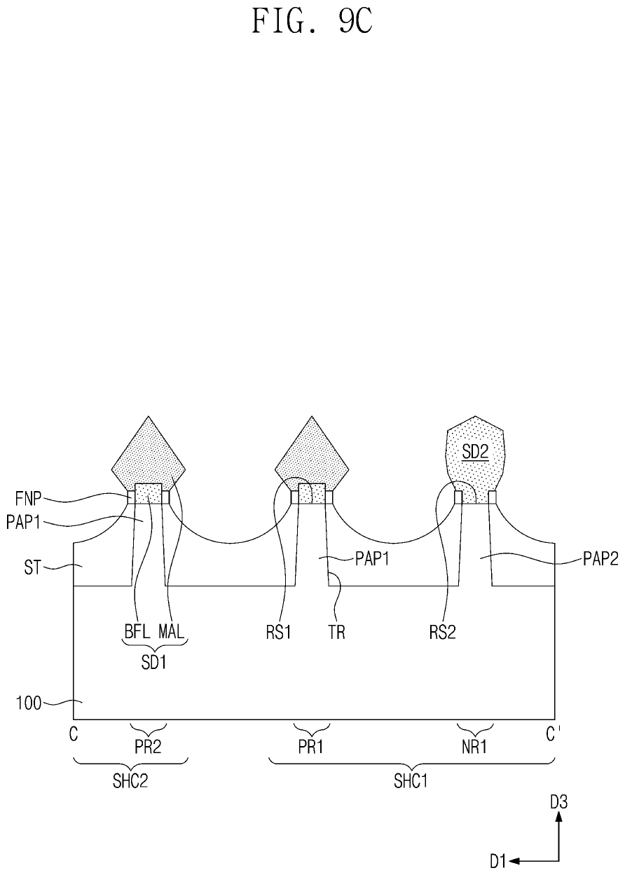

Referring to FIGS. 9A to 9C, first source/drain patterns SD1 may be correspondingly formed in the first recesses RS1. For example, a first selective epitaxial growth (SEG) process may be performed in which an inner wall of the first recess RS1 may be used as a seed layer to form a buffer layer BFL. The buffer layer BFL may be grown from a seed, and/or the semiconductor substrate 100 and the first to third semiconductor patterns SP1 to SP3 exposed by the first recess RS1. For example, the first SEG process may include chemical vapor deposition (CVD) or molecular beam epitaxy (MBE).

The buffer layer BFL may include a semiconductor element (e.g., silicon-germanium (SiGe)) whose lattice constant may be greater than a lattice constant of a semiconductor element of the semiconductor substrate 100. The buffer layer BFL may contain germanium (Ge) whose concentration may be relatively low. For example, the buffer layer BFL may not include germanium (Ge), but include only silicon (Si). Alternatively or additionally, the germanium concentration of the buffer layer BFL may range from about 0 at % to about 30 at %.

The buffer layer BFL may undergo a second SEG process to form amain layer MAL. For example, the main layer MAL may be formed to completely and/or substantially fill the first recess RS1. In an embodiment, the main layer MAL may contain germanium (Ge) whose concentration may be relatively high. For example, the germanium concentration of the main layer MAL may range from about 30 at % to about 70 at %.

In an embodiment, the main layer MAL may undergo a third SEG process to form a capping layer. The capping layer may include, but not be limited to, silicon (Si). A silicon concentration of the capping layer may range from about 98 at % to about 100 at %.

During the formation of the buffer layer BFL and the main layer MAL, impurities (e.g., boron (B), gallium (Ga), or indium (In)) may be in-situ implanted to allow the first source/drain pattern SD1 to have a p-type conductivity. Alternatively or additionally, after the formation of the first source/drain pattern SD1, impurities may be implanted into the first source/drain pattern SD1.

Second source/drain patterns SD2 may be correspondingly formed in the second recesses RS2. For example, the formation of the second source/drain patterns SD2 may include performing a selective epitaxial growth process in which inner sidewalls of the second recesses RS2 may be used as seed layers. For example, the second source/drain patterns SD2 may be formed of a substantially similar and/or the same semiconductor element (e.g., Si) as a semiconductor element of the semiconductor substrate 100.

During the formation of the second source/drain pattern SD2, impurities (e.g., phosphorus (P), arsenic (As), or antimony (Sb)) may be in-situ implanted to allow the second source/drain pattern SD2 to have n-type conductivity. Alternatively or additionally, after the formation of the second source/drain pattern SD2, impurities may be implanted into the second source/drain pattern SD2.

In an embodiment, before the formation of the second source/drain pattern SD2, a portion of the second semiconductor layer SAL exposed through the second recess RS2 may be replaced with a dielectric material to form an inner spacer IP. Thus, the inner spacers IP may be correspondingly formed between the second source/drain pattern SD2 and the second semiconductor layers SAL.

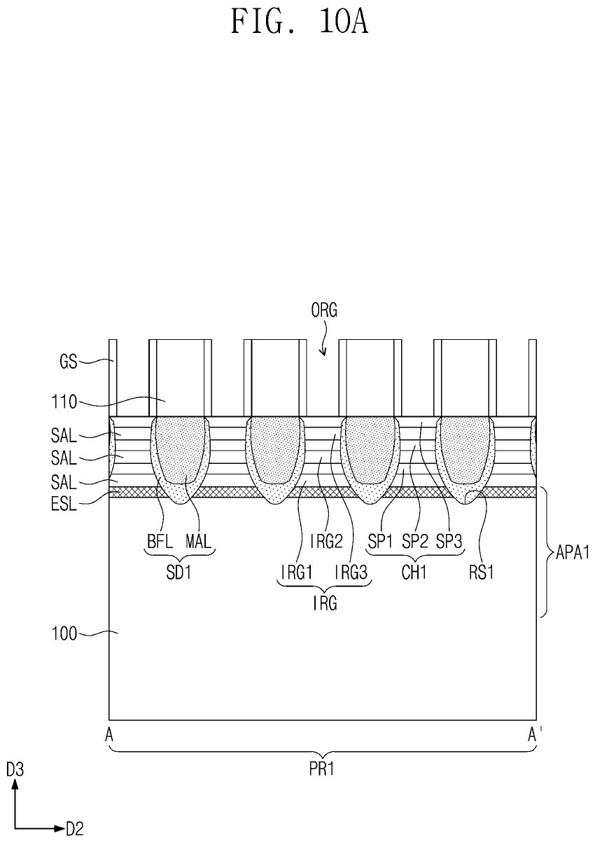

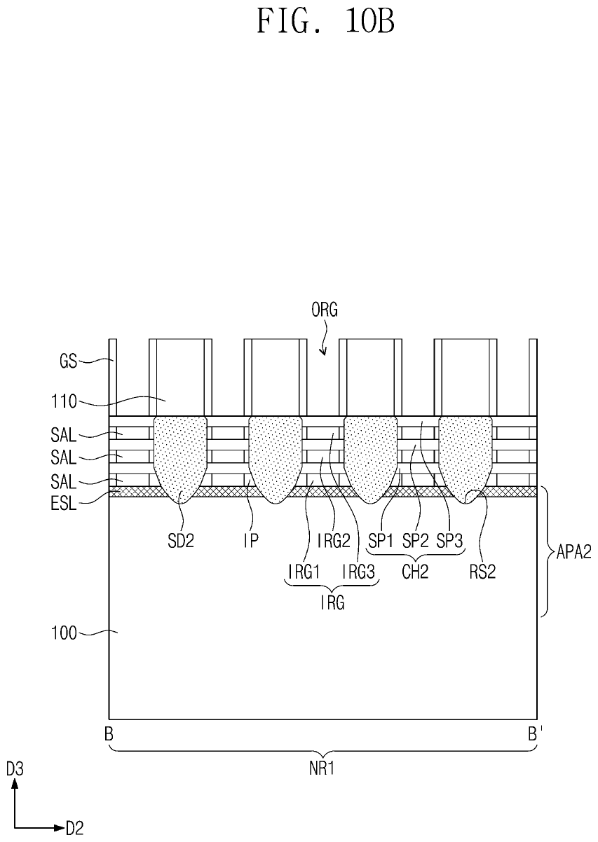

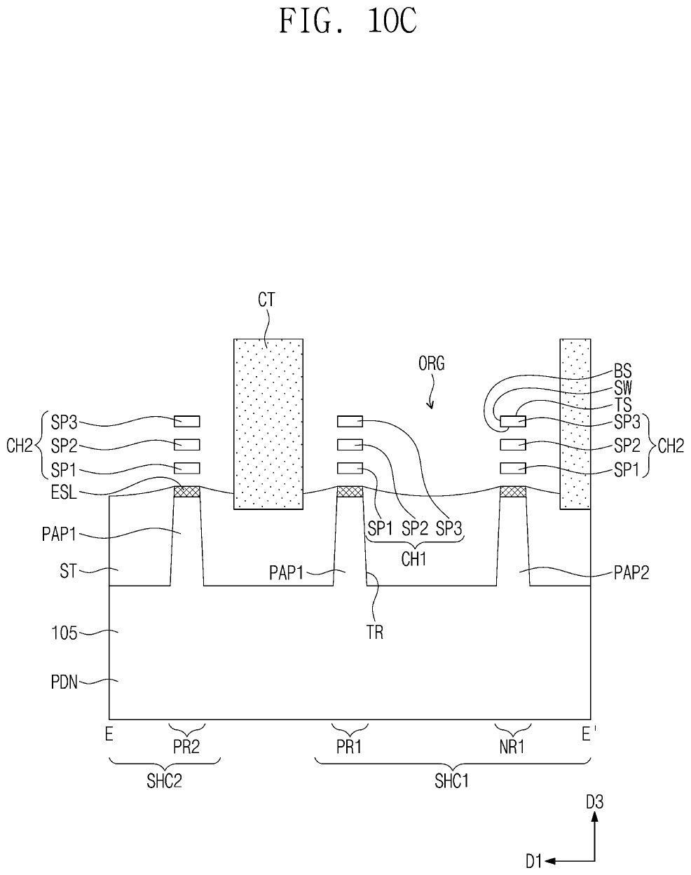

Referring to FIGS. 10A to 10C, a first interlayer dielectric layer 110 may be formed to cover the first and second source/drain patterns SD1 and SD2, the hardmask patterns MP, and the gate spacers GS. For example, the first interlayer dielectric layer 110 may include a silicon oxide (SiO) layer.

The first interlayer dielectric layer 110 may be planarized until top surfaces of the sacrificial patterns PP are exposed. For example, an etch-back and/or chemical mechanical polishing (CMP) process may be employed to planarize the first interlayer dielectric layer 110. The hardmask patterns MP may be removed during the planarization process. As a result, the first interlayer dielectric layer 110 may have a top surface that may be substantially coplanar with those of the sacrificial patterns PP and those of the gate spacers GS.

Alternatively or additionally, a photolithography process may be used to selectively open one region of the sacrificial pattern PP. For example, it may be possible to selectively open a portion of the sacrificial pattern PP on the third and fourth boundaries BD3 and BD4 of the first single height cell SHC1. The opened portion of the sacrificial pattern PP may be selectively etched and/or removed. For example, a space where the sacrificial pattern PP is removed may be filled with a dielectric material to form a gate cutting pattern CT (e.g., as shown in FIG. 10C).

In an embodiment, the exposed sacrificial patterns PP may be selectively removed. The removal of the sacrificial patterns PP may form an outer region ORG that exposes the first and second channel patterns CH1 and CH2 (e.g., as shown in FIG. 10C). In an optional or additional embodiment, the removal of the sacrificial patterns PP may include performing a wet etching process using an etchant that may selectively etch polysilicon.

The second semiconductor layers SAL exposed through the outer region ORG may be selectively removed to form inner regions IRG (e.g., as shown in FIG. 10C). For example, an etching process that selectively etches the second semiconductor layers SAL may be performed such that only the second semiconductor layers SAL may be removed while leaving the first to third semiconductor patterns SP1 to SP3. The etching process may have a high etch rate with respect to silicon-germanium (SiGe) having a relatively high germanium concentration. For example, the etching process may have a high etch rate with respect to silicon-germanium whose germanium concentration may be greater than about 10 at %.

During the etching process, the second semiconductor layers SAL may be removed from the first and second PMOSFET regions PR1 and PR2 and from the first and second NMOSFET regions NR1 and NR2. For example, the etching process may be a wet etching process. An etching material used for the etching process may promptly etch the second semiconductor layer SAL whose germanium concentrate may be relatively high. During the etching process, the first source/drain pattern SD1 on the first and second PMOSFET regions PR1 and PR2 may be protected by the buffer layer BFL whose germanium concentration may be relatively low.

Referring back to FIG. 10C, as the second semiconductor layers SAL are selectively removed, the stacked first to third semiconductor patterns SP1 to SP3 may remain on each of the first and second active patterns PAP1 and PAP2. The removal of the second semiconductor layers SAL may form first to third inner regions IRG1 to IRG3. A first inner region IRG1 may be disposed between the etch stop layer ESL and the first semiconductor pattern SP1. A second inner region IRG2 may be disposed between the first semiconductor pattern SP1 and the second semiconductor pattern SP2. A third inner region IRG3 may be disposed between the second semiconductor pattern SP2 and the third semiconductor pattern SP3.

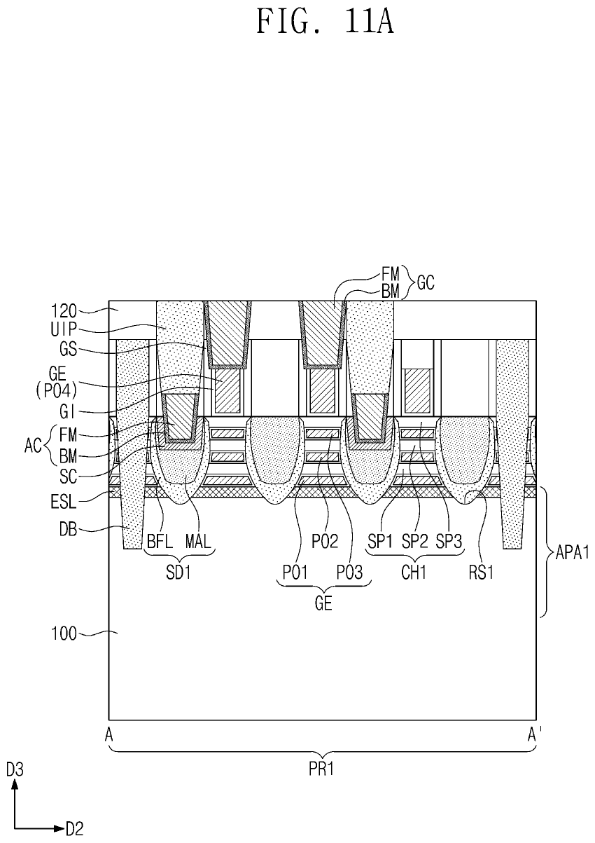

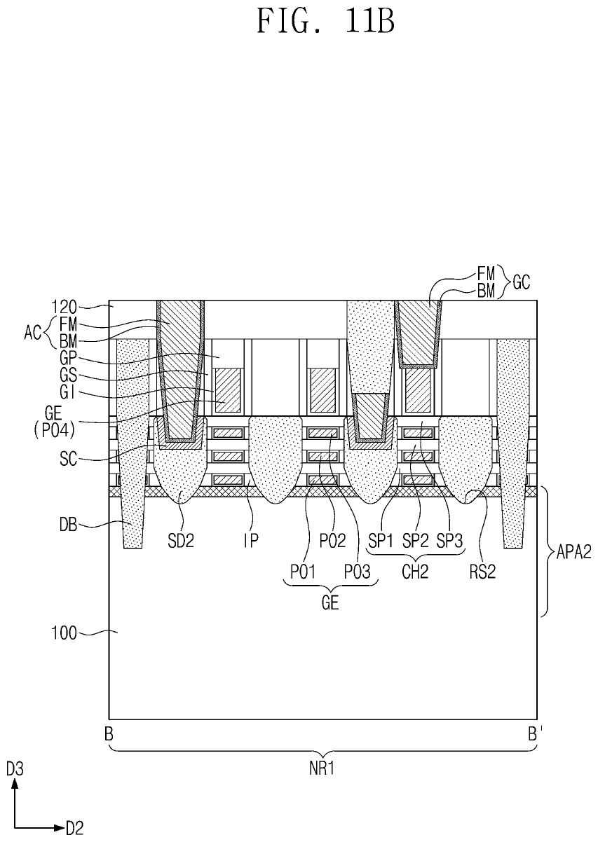

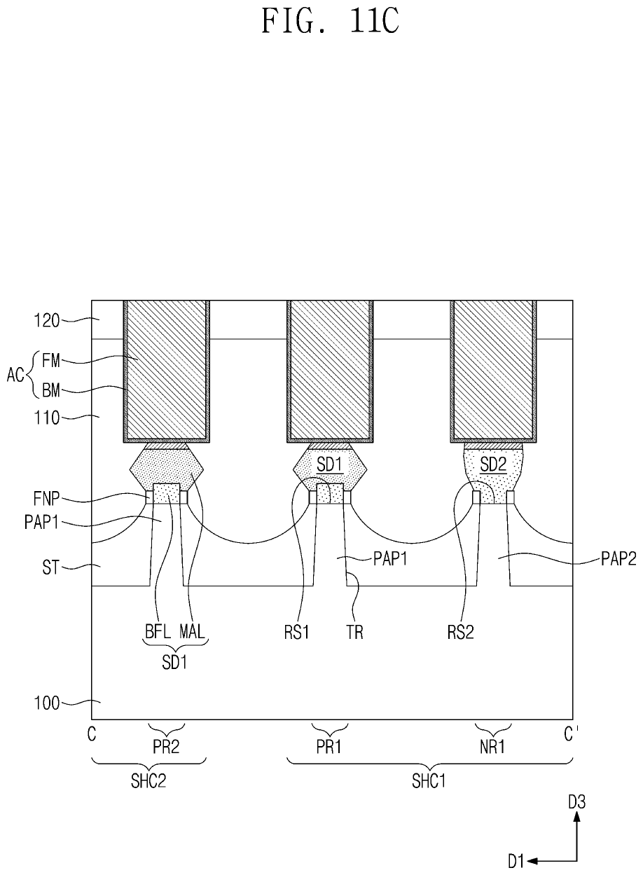

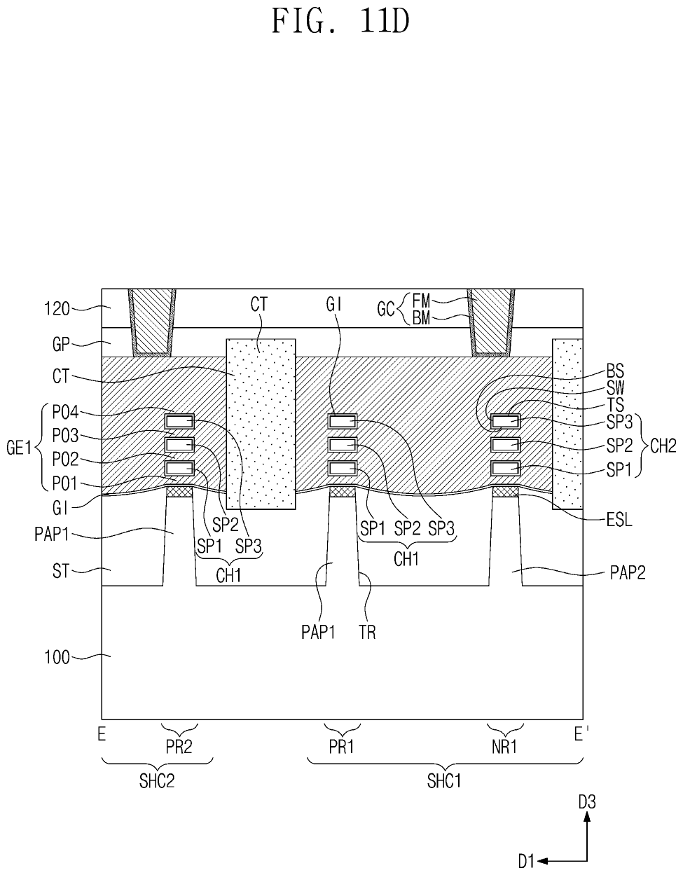

Referring to FIGS. 11A to 11D, a gate dielectric layer GI may be conformally formed on the exposed first to third semiconductor patterns SP1 to SP3. A gate electrode GE may be formed on the gate dielectric layer GI. The gate electrode GE may include first to third inner electrodes PO1 to PO3 that may be respectively formed in the first to third inner regions IRG1 to IRG3. Alternatively or additionally, the gate electrode GE may also include an outer electrode PO4 formed in the outer region ORG.

In an embodiment, the gate electrode GE may be recessed to have a reduced height. When the gate electrode GE is recessed, an upper portion of the gate cutting pattern CT may also be slightly recessed. Alternatively or additionally, a gate capping pattern GP may be formed on the recessed gate electrode GE.

A second interlayer dielectric layer 120 may be formed on the first interlayer dielectric layer 110. The second interlayer dielectric layer 120 may include, but not be limited to, a silicon oxide (SiO) layer. Alternatively or additionally, active contacts AC may be formed to penetrate the second and first interlayer dielectric layers 120 and 110, such that the first and second source/drain patterns SD1 and SD2 may be electrically connected to the active contacts AC. A gate contact GC may be formed to penetrate the second interlayer dielectric layer 120 and the gate capping pattern GP to come into electrical connection with the gate electrode GE.

The formation of each of the active contact AC and the gate contact GC may include forming a barrier pattern BM and forming a conductive pattern FM on the barrier pattern BM. The barrier pattern BM may be conformally formed to include a metal layer and a metal nitride layer. The conductive patterns FM may include metal whose resistance is low.

Referring back to FIGS. 4 and 5A to 5E, a third interlayer dielectric layer 130 may be formed on the active contacts AC and the gate contacts GC. A first metal layer M1 may be formed in the third interlayer dielectric layer 130. The first metal layer M1 may include a first wiring line M1_I electrically connected to at least one of the active contacts AC and the gate contacts GC. A fourth interlayer dielectric layer 140 may be formed on the third interlayer dielectric layer 130. A second metal layer M2 may be formed in the fourth interlayer dielectric layer 140.

Referring to FIGS. 12A and 12B, after a back-end-of-line (BEOL) process is completed, the semiconductor substrate 100 may be overturned to expose a bottom surface of the semiconductor substrate 100. The exposed semiconductor substrate 100 may be completely removed.

In an embodiment, the removal of the semiconductor substrate 100 may include allowing the bottom surface of the semiconductor substrate 100 to undergo a planarization process SAF to reduce a thickness of the semiconductor substrate 100, and performing on the semiconductor substrate 100 a cleaning process to selectively remove silicon (Si). The cleaning process may continue until the etch stop layer ESL is exposed.

For example, the semiconductor substrate 100 may be removed, and thus a first backside trench TRV1 may be formed on an area where the first active pattern PAP1 is present. Alternatively or additionally, the removal of the semiconductor substrate 100 may cause a second backside trench TRV2 to be formed on an area where the second active pattern PAP2 is present (e.g., as shown in FIG. 12B).

In an embodiment, the removal of the semiconductor substrate 100 may slightly remove lower portions of the source/drain patterns SD1 and SD2. Therefore, a concave bottom BOS may be formed on a lower portion of each of the source/drain patterns SD1 and SD2 (e.g., as shown in FIG. 12A).

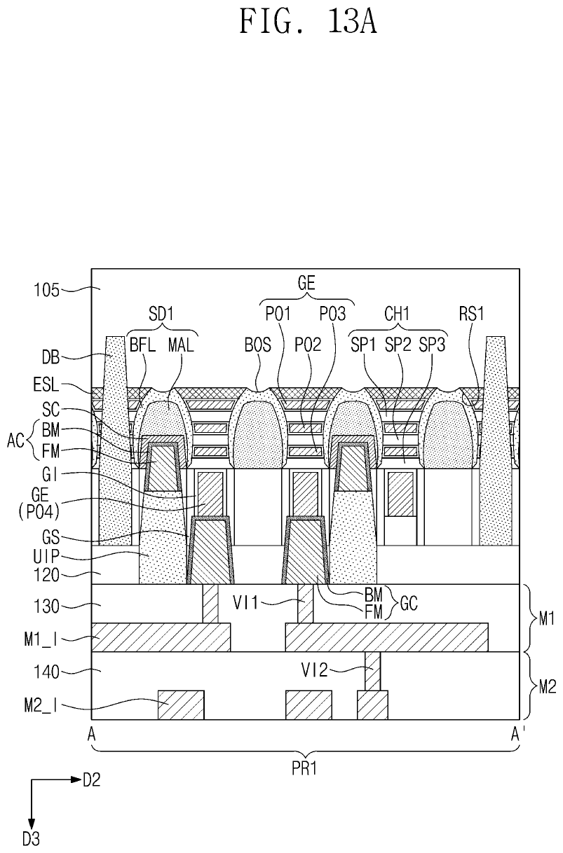

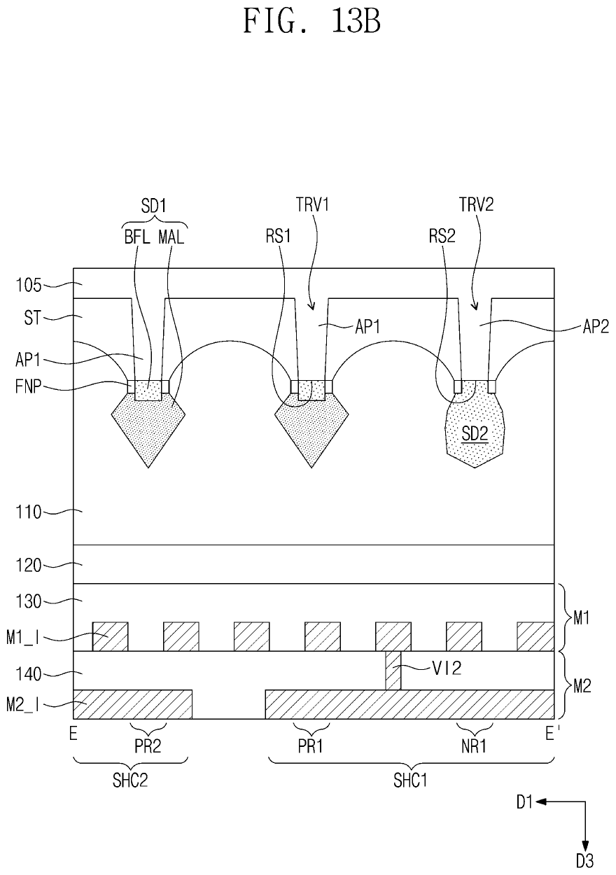

Referring to FIGS. 13A and 13B, an area where the semiconductor substrate 100 is removed may be filled with a dielectric material to form a substrate 105. The substrate 105 may include a silicon-based dielectric layer. For example, the substrate 105 may include a first dielectric pattern AP1 that may fill the first backside trench TRV1. The substrate 105 may include a second dielectric pattern AP2 that may fill the second backside trench TRV2.

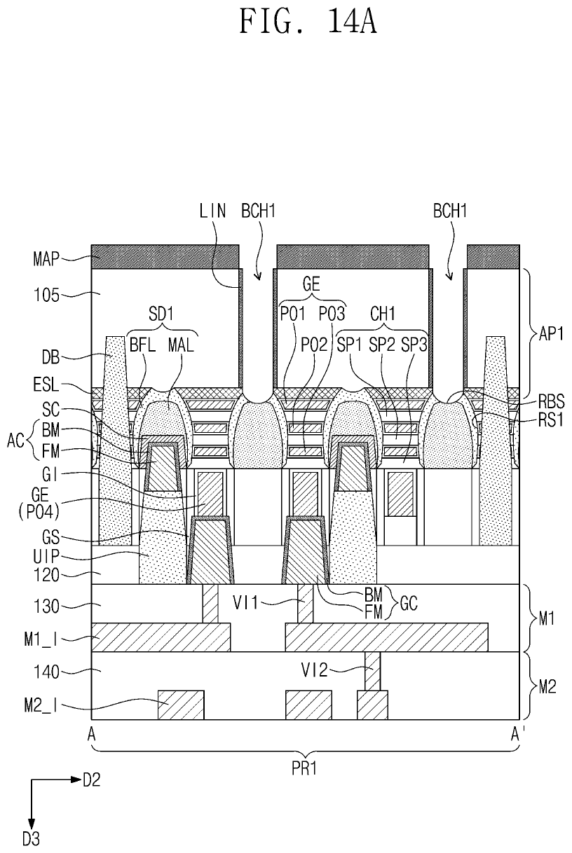

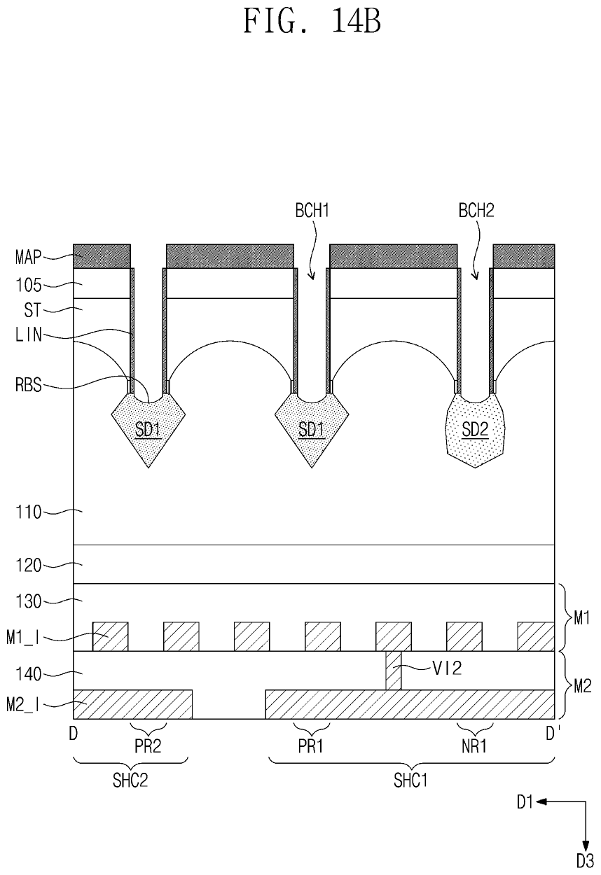

Referring to FIGS. 14A and 14B, a mask pattern MAP may be formed on the substrate 105. For example, the mask pattern MAP may be formed by a photolithography process. The substrate 105 may undergo an anisotropic etching process such that the mask pattern MAP may be used as an etching mask to form first and second backside contact holes BCH1 and BCH2. The first backside contact hole BCH1 may expose the first source/drain pattern SD1. The second backside contact hole BCH2 may expose the second source/drain pattern SD2.

A liner LIN may be formed on an inner sidewall of each of the first and second backside contact holes BCH1 and BCH2. The liner LIN may be formed to have a spacer shape. The liner LIN may include a silicon-based dielectric material (e.g, silicon oxide (SiO), silicon nitride (SiN), silicon carbon oxide (SiOC), or silicon carbon oxynitride (SiOCN)).

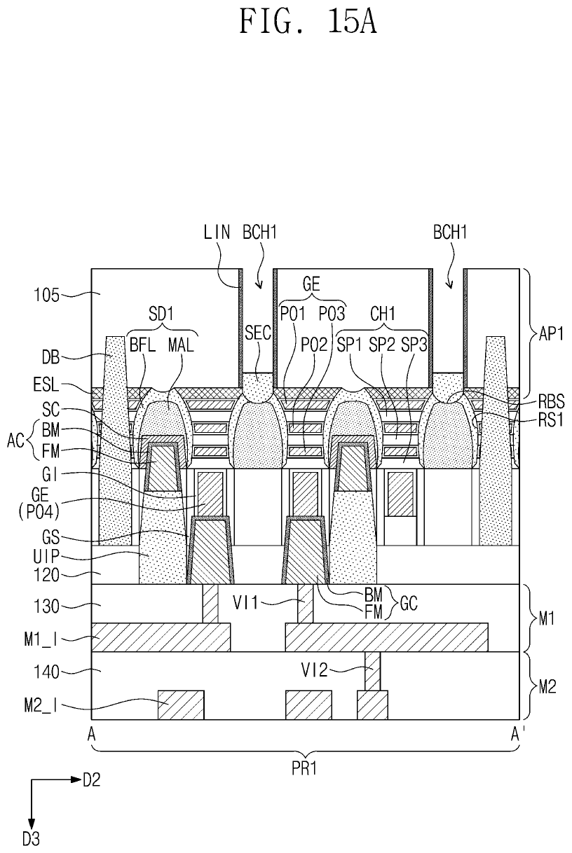

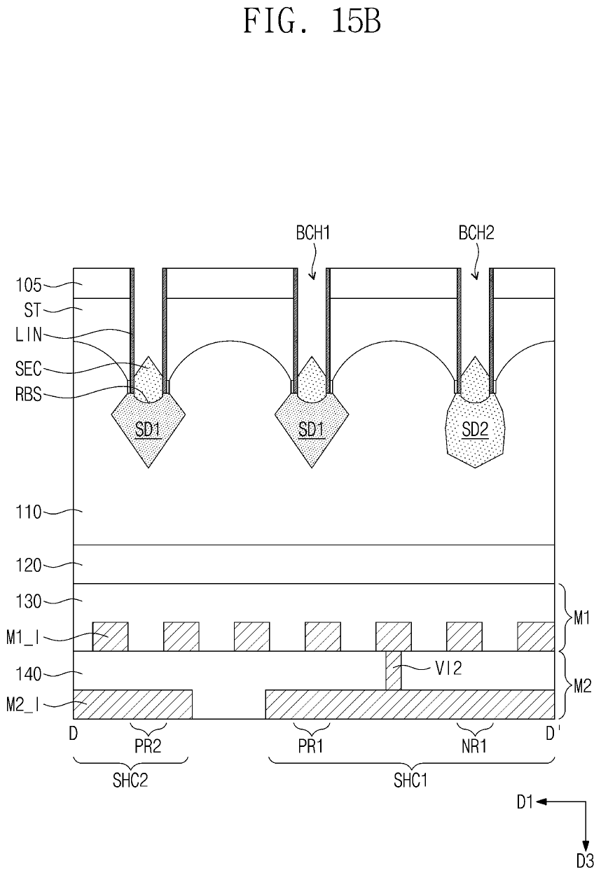

Referring to FIGS. 15A and 15B, the mask pattern MAP may be selectively removed. The first source/drain pattern SD1 exposed by the first backside contact hole BCH1 may undergo a selective epitaxial growth (SEG) process to form an epitaxial contact SEC. The epitaxial contact SEC may vertically grow while filling the first backside contact hole BCH1. For example, the epitaxial contact SEC may be formed in a self-alignment manner along the first backside contact hole BCH1 from the first source/drain pattern SD1. Impurities (e.g., boron (B), gallium (Ga), indium (In), or aluminum (Al)) may be in-situ implanted while the epitaxial contact SEC is formed on the first source/drain pattern SD1.

The second source/drain pattern SD2 exposed by the second backside contact hole BCH2 may undergo a selective epitaxial growth (SEG) process to form an epitaxial contact SEC. The formation of the epitaxial contact SEC on the second source/drain pattern SD2 may be substantially similar and/or may be the same as the formation of the epitaxial contact SEC on the first source/drain pattern SD1, except that impurities such as phosphorus (P), arsenic (As), or antimony (Sb) may be used.

Referring back to FIGS. 4 and 5A to 5E, the first and second backside contact holes BCH1 and BCH2 may be filled with metal to form a contact plug PCP and a metal-semiconductor compound layer SC. A first backside contact BSC1 may be implemented by the epitaxial contact SEC, the metal-semiconductor compound layer SC, and the contact plug PCP in the first backside contact hole BCH1. A second backside contact BSC2 may be implemented by the epitaxial contact SEC, the metal-semiconductor compound layer SC, and the contact plug PCP in the second backside contact hole BCH2.

Lower power lines VPR1 to VPR3 may be formed on the substrate 105. One of the lower power lines VPR1 to VPR3 may be connected to at least one of the first and second backside contacts BSC1 and BSC2. A power delivery network layer PDN may be formed on the lower power lines VPR1 to VPR3. The power delivery network layer PDN may be formed to apply a source voltage or a drain voltage to the lower power lines VPR1 to VPR3.

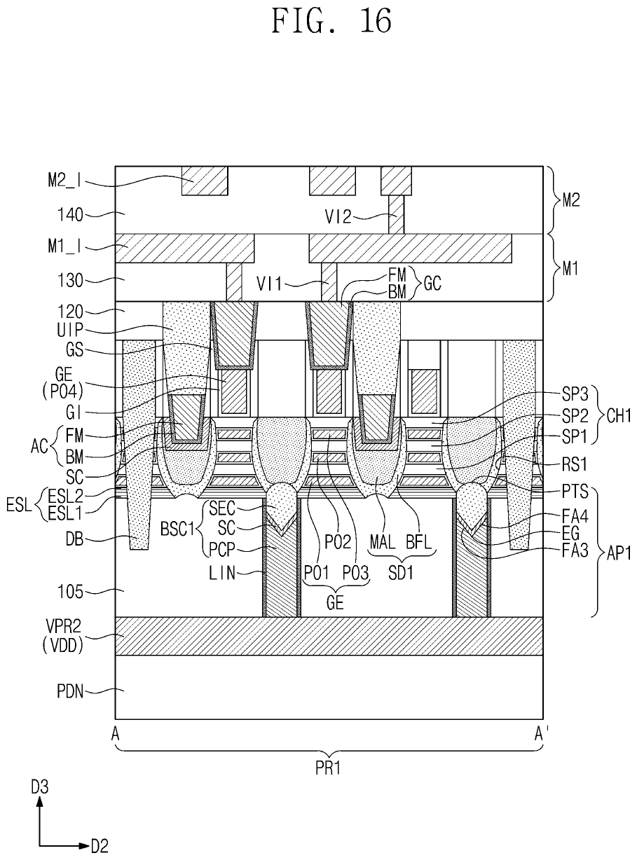

FIG. 16 illustrates a cross-sectional view taken along line A-A′ of FIG. 4, showing a semiconductor device, according to some embodiments. The semiconductor device of FIG. 16 may include and/or may be similar in many respects to the semiconductor devices described above with reference to FIGS. 4 and 5A to 5E, and may include additional features not mentioned above. Thus, redundant descriptions of the semiconductor device may be omitted.

Referring to FIG. 16, an etch stop layer ESL may be interposed between the first inner electrode PO1 and the substrate 105. The etch stop layer ESL may be a multiple layer. For example, the etch stop layer ESL may include first and second layers ESL1 and ESL2 that may be alternately stacked. The first layer ESL1 and the second layer ESL2 may have their compositions different from each other. For example, the first layer ESL1 may include, but not be limited to, silicon (Si). The second layer ESL2 may include, but not be limited to, silicon (Si) doped with oxygen (O), carbon (C), or a combination thereof. In an optional or additional embodiment, the first and second layers ESL1 and ESL2 may have a substantially similar and/or the same composition.

As shown in FIG. 16, a bottom surface of the epitaxial contact SEC may include a third crystal plane FA3 and a fourth crystal plane FA4. Each of the third and fourth crystal planes FA3 and FA4 may be a {111} plane. The third and fourth crystal planes FA3 and FA4 may meet each other to define a sharp corner EG. The corner EG may be a lowermost point of the epitaxial contact SEC.

According to the present disclosure, an etch stop layer may be used to replace a semiconductor substrate with a dielectric substrate. It may thus be possible to prevent and/or reduce a leakage current from a transistor to a substrate and/or to improve electrical properties of devices.

According to the present disclosure, a backside contact may be connected in a self-alignment manner through an epitaxial contact to a source/drain pattern. Consequently, when the epitaxial contact has a high impurity concentration and a convex top surface, a reduced contact resistance may be provided between the backside contact and the source/drain pattern. As a result, a semiconductor device including a lower power line may have increased reliability and improved electrical properties, when compared to a related semiconductor device.

Although some embodiments of present disclosure have been described with reference to accompanying figures, it may be understood that various changes in form and details may be made therein without departing from the spirit and scope of the present disclosure. As such, it may be understood that the embodiments described above are just illustrative but not limitative in all aspects.

What is claimed is:

1. A semiconductor device, comprising:
a substrate;
a lower power line buried in a lower portion of the substrate;
a source/drain pattern on the substrate; and
a backside contact that penetrates the substrate and electrically couples the lower power line to the source/drain pattern,
wherein the backside contact comprises:
an epitaxial pattern coupled to a lower portion of the source/drain pattern;
a contact plug coupled to the lower power line; and
a metal-semiconductor compound layer between the epitaxial pattern and the contact plug, and
wherein the epitaxial pattern comprises a top surface that protrudes toward the source/drain pattern.

2. The semiconductor device of claim 1, wherein a concentration of impurities in the epitaxial pattern is greater than a maximum concentration of impurities in the source/drain pattern.

3. The semiconductor device of claim 1, wherein:
the epitaxial pattern comprises a {111} crystal plane, and
at least a portion of the epitaxial pattern is covered with the metal-semiconductor compound layer.

4. The semiconductor device of claim 1, wherein:
the source/drain pattern comprises a buffer layer and a main layer on the buffer layer,
the source/drain pattern comprises silicon-germanium,
a germanium concentration of the main layer is in a range of about 30 at % to about 70 at %, and
at least a portion of the epitaxial pattern is in contact with the main layer.

5. The semiconductor device of claim 1, further comprising:
a device isolation layer between the source/drain pattern and the substrate,
wherein the backside contact penetrates the device isolation layer.

6. The semiconductor device of claim 5, further comprising:
a liner between the device isolation layer and the backside contact.

7. The semiconductor device of claim 1, wherein the substrate comprises a dielectric substrate.

8. The semiconductor device of claim 1, further comprising:
a power delivery network layer below the substrate,
wherein the power delivery network layer is configured to provide the lower power line with at least one of a source voltage and a drain voltage.

9. A semiconductor device, comprising:
a dielectric substrate;
an etch stop layer on the dielectric substrate;
a channel pattern on the etch stop layer, wherein the channel pattern comprises a plurality of semiconductor patterns that are stacked and spaced apart from each other,
a source/drain pattern coupled to the channel pattern;
a gate electrode on the channel pattern, wherein the gate electrode comprises a plurality of inner electrodes that are correspondingly interposed between the plurality of semiconductor patterns;
a lower power line below the dielectric substrate; and
a backside contact that penetrates the dielectric substrate and electrically couples the lower power line to the source/drain pattern,
wherein the etch stop layer comprises silicon doped with at least one of oxygen (O) and carbon (C), and
wherein the etch stop layer is between the dielectric substrate and a lowermost electrode of the plurality of inner electrodes.

10. The semiconductor device of claim 9, wherein the backside contact comprises:
an epitaxial pattern coupled to a lower portion of the source/drain pattern;
a contact plug coupled to the lower power line; and
a metal-semiconductor compound layer between the epitaxial pattern and the contact plug.

11. The semiconductor device of claim 10, wherein:
the epitaxial pattern comprises a {111} crystal plane, and
at least a portion of the epitaxial pattern is covered with the metal-semiconductor compound layer.

12. The semiconductor device of claim 10, wherein a concentration of impurities in the epitaxial pattern is greater than a maximum concentration of impurities in the source/drain pattern.

13. The semiconductor device of claim 10, wherein the epitaxial pattern comprises a top surface that vertically protrudes toward the source/drain pattern.

14. The semiconductor device of claim 9, wherein the etch stop layer comprises a monocrystalline material.

15. The semiconductor device of claim 9, further comprising:
a power delivery network layer below the dielectric substrate,
wherein the power delivery network layer is configured to provide the lower power line with at least one of a source voltage and a drain voltage.

16. A semiconductor device, comprising:
a dielectric substrate;
an etch stop layer on the dielectric substrate;
a channel pattern on the etch stop layer, wherein the channel pattern comprises a plurality of semiconductor patterns that are stacked and spaced apart from each other,
a source/drain pattern coupled to the channel pattern;
a gate electrode on the channel pattern;
a gate dielectric layer between the gate electrode and the channel pattern;
a gate spacer on a sidewall of the gate electrode;
a gate capping pattern on a top surface of the gate electrode;
an interlayer dielectric layer that covers the source/drain pattern and the gate capping pattern;
a gate contact that penetrates the interlayer dielectric layer and the gate capping pattern and is electrically coupled to the gate electrode;
a first metal layer on the interlayer dielectric layer, wherein the first metal layer comprises a first wiring line electrically coupled to the gate contact;
a lower power line below the dielectric substrate; and
a backside contact that penetrates the dielectric substrate and electrically couples the lower power line to the source/drain pattern,
wherein the backside contact comprises:
an epitaxial pattern coupled to a lower portion of the source/drain pattern;
a contact plug coupled to the lower power line; and
a metal-semiconductor compound layer between the epitaxial pattern and the contact plug, and
wherein a concentration of impurities in the epitaxial pattern is greater than a maximum concentration of impurities in the source/drain pattern.

17. The semiconductor device of claim 16, wherein:
the epitaxial pattern comprises a {111} crystal plane, and
at least a portion of the epitaxial pattern is covered with the metal-semiconductor compound layer.

18. The semiconductor device of claim 16, wherein the epitaxial pattern comprises a top surface that vertically protrudes toward the source/drain pattern.

19. The semiconductor device of claim 16, wherein
the etch stop layer comprises silicon doped with at least one of oxygen (O) and carbon (C), and
the etch stop layer comprises a monocrystalline material.

20. The semiconductor device of claim 16, further comprising:
a power delivery network layer below the dielectric substrate,
wherein the power delivery network layer is configured to provide the lower power line with at least one of a source voltage and a drain voltage.
